(19) United States
(12) Patent Application Publication
(10) Pub. No.: US 2026/0206537 A1
(43) Pub. Date: Jul. 16, 2026

(54) POST-PLACEMENT WAFER-CENTERING SYSTEMS FOR SEMICONDUCTOR PROCESSING TOOLS

(71) Applicant: Lam Research Corporation, Fremont, CA (US)

(72) Inventors: Nick Ray Linebarger, Jr., Tualatin, OR (US); Jacob Lee Hiester, Newberg, OR (US)

(21) Appl. No.: 19/131,267

(22) PCT Filed: Nov. 17, 2023
(86) PCT No.: PCT/US2023/080420

§ 371 Date: May 20, 2025

Related U.S. Application Data
(60) Provisional application No. 63/384,623, filed on Nov. 22, 2022.

(51) Int. Cl. H10P 72/50; H10P 72/76

(52) U.S. Cl. CPC H10P 72/50; H10P 72/7611; H10P 72/7618

(57) ABSTRACT

Disclosed herein are systems and techniques for post-placement centering of semiconductor wafers, i.e., centering of semiconductor wafers after they have already been placed on pedestals or, more specifically, on a pedestal base. Such systems also allow for such centering to be performed in an open-loop manner, e.g., without requiring determination of how much a semiconductor wafer is off-center from a desired location. Such capabilities allow for wafers to be centered relative to pedestal bases in multi-station semiconductor processing tools such as those described above-semiconductor processing tools in which AWC systems have limited or no efficacy.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

When semiconductor wafers are placed into semiconductor processing tools, e.g., onto a pedestal of a semiconductor processing chamber of a semiconductor processing tool, it is typically desirable to manage the placement of the semiconductor wafer on the pedestal such that the center of the wafer is centered on the pedestal (or within some predetermined zone associated with an acceptable level of processing uniformity). This is typically done using an automatic wafer centering system (AWC). In an AWC, two or more optical beam sensors are arranged at the entrance to the semiconductor processing chamber so as to detect when the edge of a semiconductor wafer being carried by a wafer-handling robot passes through them. By using the kinematic configuration of the wafer handling robot when each such edge-detection event occurs, in combination with a known wafer diameter and calibration data that relates the optical beam sensor locations to the desired target zone for the wafer center relative to the pedestal, the AWC is able to determine how much the center of the semiconductor wafer will be off from the target zone once placed by the wafer-handling robot (assuming the wafer-handling robot follows its default path). The AWC may then cause the wafer-handling robot to modify the path that it follows to compensate for such deviation, resulting in the semiconductor wafer being placed on-center on the pedestal.

### SUMMARY

Details of one or more implementations of the subject matter described in this specification are set forth in the accompanying drawings and the description below. Other features, aspects, and advantages will become apparent from the description, the drawings, and the claims.

In some implementations, a semiconductor processing tool for processing a semiconductor wafer having a diameter of D and thickness T may be provided. The semiconductor processing tool may include a semiconductor processing chamber having a plurality of surfaces defining an interior volume thereof. The semiconductor processing tool may also include a pedestal base configured to support a semiconductor wafer during wafer processing operations, the pedestal base located within the interior volume and including one or more wafer support features that are configured to support the semiconductor wafer when the semiconductor wafer is placed on the pedestal base. The one or more wafer support features may define a first reference plane that is coincident with an underside of the semiconductor wafer when the semiconductor wafer is supported by the one or more wafer support features. The semiconductor processing tool may further include a showerhead having a first surface with a plurality of gas distribution ports distributed thereacross, the first surface facing towards, and positioned above, the pedestal base, one or more wafer-centering features collectively having one or more radially inward-facing wafer-centering surfaces that are positioned radially outward from or circumscribing a reference circle having a diameter of D or greater, and one or more movement mechanisms including at least a first movement mechanism that is configured to move the pedestal base or the one or more wafer-centering features laterally. The first movement mechanism may enable the one or more wafer-centering features to adjust a position of the semiconductor wafer relative to the pedestal base while the semiconductor wafer is supported by the pedestal base. The semiconductor processing tool may also include a controller configured to control at least the first movement mechanism to cause the pedestal base or the one or more wafer-centering features to move relative to the other of the pedestal base or the one or more wafer-centering features.

In some implementations of the semiconductor processing tool, the one or more wafer-centering features may be fixed in space with respect to the showerhead and at least a portion or portions of the one or more radially inward-facing wafer-centering surfaces may be located at an elevation lower than the first surface.

In some implementations of the semiconductor processing tool, the one or more wafer-centering features may project downward from the showerhead toward the pedestal base.

In some implementations of the semiconductor processing tool, the one or more wafer-centering features may be fixed in space with respect to the semiconductor processing chamber and may extend downward into pass-through apertures in the showerhead.

In some implementations of the semiconductor processing tool, the showerhead and the pedestal base may both be configured to be movable along an axis perpendicular to the first reference plane relative to the semiconductor processing chamber, the showerhead may be configured to be movable between a first configuration and a second configuration relative to the semiconductor processing chamber, first ends of the one or more wafer-centering features may extend past the first surface of the showerhead and towards the pedestal base when the showerhead is in the first configuration, the first ends of the one or more wafer-centering features may not extend past the first surface of the showerhead when the showerhead is in the second configuration, the pedestal base may be configured to be movable between a third configuration and a fourth configuration relative to the semiconductor processing chamber, the first reference plane may be within a distance T of the first ends of the one or more wafer-centering features when the pedestal base is in the third configuration, and the first reference plane may be more than the distance T away from the first ends of the one or more wafer-centering features when the pedestal base is in the fourth configuration.

In some implementations of the semiconductor processing tool, the one or more wafer-centering features may extend downward into pass-through apertures in the showerhead, the semiconductor processing tool may further include one or more actuators configured to be movable between a first position and a second position, the one or more wafer-centering features may be connected, directly or indirectly, with the one or more actuators such that the one or more wafer-centering features move along an axis perpendicular to the first reference plane when the one or more actuators are moved between the first position and the second position, the one or more wafer-centering features may protrude past the first surface of the showerhead when the one or more actuators are in the first position, and the one or more wafer-centering features may be above the first surface of the showerhead when the one or more actuators are in the second position.

In some implementations of the semiconductor processing tool, the one or more wafer-centering features may be fixed in space with respect to the semiconductor processing chamber and may extend upward into pass-through apertures in the pedestal base.

In some implementations of the semiconductor processing tool, the first movement mechanism may be configured to move the pedestal base both laterally relative to the one or more wafer-centering features and also along an axis perpendicular to the first reference plane, the first movement mechanism may be further configured to move the pedestal base between a first configuration and a second configuration relative to the semiconductor processing chamber, first ends of the one or more wafer-centering features may extend past the first reference plane when the pedestal base is in the first configuration, and the first ends of the one or more wafer-centering features may not extend past the first reference plane when the pedestal base is in the second configuration.

In some implementations of the semiconductor processing tool, the one or more wafer-centering features may extend upward into pass-through apertures in the pedestal base, the semiconductor processing tool may further include one or more actuators configured to be movable between a first position and a second position, the one or more wafer-centering features may be connected, directly or indirectly, with the one or more actuators such that the one or more wafer-centering features move along an axis perpendicular to the first reference plane and relative to the semiconductor processing chamber when the one or more actuators are moved between the first position and the second position, the one or more wafer-centering features may protrude past the first reference plane when the one or more actuators are in the first position, and the one or more wafer-centering features may be below the first reference plane when the one or more actuators are in the second position.

In some implementations of the semiconductor processing tool, the one or more wafer-centering features may include an annular wall element that encircles the showerhead, the semiconductor processing tool may further include one or more actuators configured to be movable between a first position and a second position, the annular wall element may be connected, directly or indirectly, with the one or more actuators such that the annular wall element moves along an axis perpendicular to the first reference plane when the one or more actuators are moved between the first position and the second position, the annular wall element may protrude past the first surface when the one or more actuators are in the first position, and the annular wall element may be higher when the one or more actuators are in the second position than when the one or more actuators are in the first position.

In some implementations of the semiconductor processing tool, the first movement mechanism may be configured to move the pedestal base at least laterally relative to the semiconductor processing chamber and the showerhead.

In some implementations of the semiconductor processing tool, the first movement mechanism may be configured to move the showerhead at least laterally relative to the semiconductor processing chamber and the pedestal base.

In some implementations of the semiconductor processing tool, the one or more wafer-centering features may be cylindrical posts.

In some implementations of the semiconductor processing tool, the one or more radially inward-facing wafer-centering surfaces may be provided by an axially symmetric wall surface having an inner diameter larger than D.

In some implementations of the semiconductor processing tool, the one or more radially inward-facing wafer-centering surfaces may be a plurality of arcuate surfaces, each arcuate surface may have a radius larger than half of D, and the arcuate surfaces may all have the same radius and may share a common center point.

In some implementations of the semiconductor processing tool, the one or more radially inward-facing wafer-centering surfaces may be a plurality of radially inward-facing centering surfaces and the radially inward-facing centering surfaces may circumscribe the reference circle.

In some implementations of the semiconductor processing tool, the first movement mechanism may be a hexapod mechanism including a base mount, a movable mount that supports the one of the pedestal base and the one or more wafer-centering features that the first movement mechanism is configured to move, and six linear actuators, each linear actuator connected at one end with the base mount and at an opposing end with the movable mount. In such an implementation, the hexapod mechanism may be configured to cause the movable mount to at least move laterally relative to the base mount, via actuation of the linear actuators, responsive to one or more control signals provided by the controller.

In some implementations of the semiconductor processing tool, the first movement mechanism may include an XY translation stage having a first linear translation mechanism configured to cause the one of the pedestal base and the one or more wafer-centering features that the first movement mechanism is configured to move to translate along a first lateral axis responsive to one or more control signals provided by the controller. The XY translation stage may also have a second linear translation mechanism configured to cause the one of the pedestal base and the one or more wafer-centering features that the first movement mechanism is configured to move to translate along a second lateral axis responsive to the one or more control signals provided by the controller. In such implementations, the first lateral axis and the second lateral axis may not be parallel to one another and, in some further implementations thereof, the first lateral axis may be orthogonal to the second lateral axis.

In some implementations of the semiconductor processing tool, the first movement mechanism may include an R-theta mechanism having a rotational actuator with a base portion and a rotatable portion and a linear translation mechanism with a first portion and a second portion. The rotational actuator may be configured to cause the rotatable portion to rotate about a rotational axis relative to the base portion responsive to one or more control signals provided by the controller, the linear translation mechanism may be configured to cause the second portion to translate along a radial axis relative to the first portion responsive to the one or more control signals provided by the controller, the second portion of the linear translation mechanism may support the one of the pedestal base and the one or more wafer-centering features that the first movement mechanism is configured to move, the rotatable portion of the rotational actuator may support the first portion of the linear translation mechanism, and the radial axis may be orthogonal to an axis that is parallel to the rotational axis.

In some implementations of the semiconductor processing tool, the controller may be further configured to control the one or more movement mechanisms to cause the pedestal base and the one or more wafer-centering features to transition between at least a first relative configuration and a second relative configuration. At least a portion of at least one wafer-centering feature of the one or more wafer-centering features may, in the first relative configuration, be between the first reference plane and a second reference plane that is parallel to, and positioned a distance T above, the first reference plane and, in the second relative configuration, may not be in between the first reference plane and the second reference plane.

In some implementations of the semiconductor processing tool, the controller may be further configured to control the first movement mechanism so as to cause the pedestal base to perform one or more circular orbits having a diameter or diameters less than or equal to the diameter of the reference circle minus D.

In some implementations of the semiconductor processing tool, the controller may be further configured to control the first movement mechanism so as to cause the pedestal base to perform multiple circular orbits having increasingly larger diameters that are each less than or equal to the diameter of the reference circle minus D.

In some implementations of the semiconductor processing tool, the controller may be further configured to control the first movement mechanism so as to cause the pedestal base to follow a path that spirals outward from a center point before following an arcuate or circular path having a diameter equal to the diameter of the reference circle minus D.

In some implementations of the semiconductor processing tool, the controller may be further configured to control the first movement mechanism so as to cause the pedestal base to move along plurality of paths that radiate outward from a center region and towards multiple locations that lie along the one or more radially inward-facing wafer-centering surfaces. In addition to the above-listed implementations, other implementations evident from the discussion below and the Figures are to be understood to also fall within the scope of this disclosure.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an example simplified representation of a pedestal, semiconductor wafer, showerhead, and wafer-centering features.

FIGS. 2a through 2l depict a plan view of the elements shown in FIG. 1 during various phases of a wafer-centering process.

FIGS. 3a through 3d depict different movement paths that may be used to provide wafer-centering as discussed herein.

FIGS. 4a through 4c depict an example semiconductor processing tool that has a wafer-centering capability as discussed herein.

FIG. 5 depicts an example movement mechanism that may be used as the first movement mechanism.

FIG. 6 depicts another example movement mechanism that may be used as the first movement mechanism.

FIG. 7 depicts an example of a semiconductor processing tool that is configured to provide for post-placement wafer centering using a movable showerhead.

FIGS. 8a and 8b depict an example semiconductor processing tool in which wafer-centering features are fixed in space with respect to the semiconductor processing chamber.

FIGS. 9a and 9b depict a semiconductor processing tool that is similar to the semiconductor processing tool of FIGS. 8a and 8b but with some modification.

FIGS. 10a and 10b depict an example semiconductor processing tool in which the wafer-centering features are not fixed with respect to the semiconductor processing chamber or showerhead.

FIGS. 11a and 11b depict an implementation similar that of FIGS. 10a and 10b, but with some key differences.

FIGS. 12a and 12b depict an example semiconductor processing tool having a single wafer-centering feature.

FIGS. 13a and 13b depict plan and side cross-section views, respectively, of a showerhead having a wafer-centering feature that consists of an axially symmetric wall surface.

FIGS. 14a and 14b depict plan and side cross-section views, respectively, of a showerhead having a plurality of wafer-centering features that each provide an arcuate radially inward-facing wafer-centering surface.

FIGS. 15a through 15c depict top (FIG. 15a) and side views (FIGS. 15b and 15c) of an example showerhead and pedestal base that include wafer-centering functionality similar to that shown in FIGS. 14a and 14b

FIGS. 16a and 16b depict plan and side cross-section views, respectively, of a showerhead having a plurality of wafer-centering features that are each a cylindrical post.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

While AWC systems are in widespread use and generally provide reliable and high-precision wafer-placement capability, such systems have limitations that make them ill-suited for use in certain contexts, e.g., in systems that may transport multiple semiconductor wafers into a chamber at the same time, systems where the apparatus that places semiconductor wafers onto pedestals may not have sufficient degrees of freedom or sufficient precision to actually correct out any misalignment of the semiconductor wafer, and/or systems in which it is not possible to measure the location of the semiconductor wafer relative to the wafer-transfer system that is moving it.

For example, in some semiconductor processing tools, a chamber may be provided that has multiple pedestals located within it to allow for the simultaneous processing of multiple semiconductor wafers. In some such systems, the wafer-handling robot that may be used to move the semiconductor wafers into and out of the chamber may have an end effector that supports two wafers in a stacked arrangement. Thus, when the stacked wafers transit through the optical beams of an AWC, the AWC may not be able to determine which wafer's edge is being detected, making it impossible to determine which wafer each measurement belongs to.

In another example, a semiconductor processing tool having multiple pedestals within a common chamber may use a rotational indexer to move wafers from pedestal to pedestal within the chamber. In such a system, the pedestals may be arranged in a circular array around a center axis of the rotational indexer. The rotational indexer may have a plurality of arms that extend radially outward from a central hub that is configured to rotate about the center axis. Each arm may have a wafer support at the end that is radially outward from the central hub. When semiconductor wafers are transferred between such pedestals, the semiconductor wafers may, for example, first be raised off of their respective pedestals by a lift pin mechanism. The rotational indexer may then be rotated so as to position each wafer support under one of the semiconductor wafers, and the lift pins then lowered to place the semiconductor wafers on the wafer supports. The rotational indexer may then be rotated so as to position each semiconductor wafer over a new pedestal, and the lift pins may then be raised again to lift the semiconductor wafers off of the wafer supports. The rotational indexer may then be rotated to a position in which the indexer arms are no longer interposed between the semiconductor wafers and the pedestals, and the lift pins then lowered to lower the semiconductor wafers onto the pedestals. Such rotational indexers typically have one degree of freedom (rotation about the center axis) or very limited degrees of freedom, making them unable to be able to correct out any potential wafer misalignment.

Such systems may also encounter difficulty in determining what the wafer misalignment is in the first place—it is typically not feasible to place optical beam sensors within the interior of the semiconductor processing chamber, so there may be no way to determine how off-center each semiconductor wafer is with respect to its ideally centered location.

The systems discussed herein allow for post-placement centering of semiconductor wafers, i.e., centering of semiconductor wafers after they have already been placed on pedestals or, more specifically, on a pedestal base. Such systems also allow for such centering to be performed in an open-loop manner, e.g., without requiring determination of how much a semiconductor wafer is off-center from a desired location. Such capabilities allow for wafers to be centered relative to pedestal bases in multi-station semiconductor processing tools such as those described above—semiconductor processing tools in which AWC systems have limited or no efficacy.

A pedestal generally includes a stem or other support structure and a pedestal base that is supported by the stem or support structure; the pedestal base then supports the semiconductor wafer during wafer processing operations. The pedestal base is located within an interior volume of a semiconductor processing chamber. The stem may also be located within the interior volume of the semiconductor processing tool, but may also extend through a wall of the semiconductor processing chamber and be supported by equipment outside of the semiconductor processing chamber. For example, a pedestal may be connected with a vertical lift mechanism that may be controlled to move the pedestal up and down relative to the semiconductor processing chamber. Such a vertical lift mechanism may be located outside of the semiconductor processing chamber, requiring that the stem extend through a wall of the semiconductor processing chamber in order to connect with the vertical lift mechanism.

Pedestal bases are generally sized larger than semiconductor wafers and may include features such as heaters, cooling channels, electrostatic chucks, vacuum chucks, radio-frequency (RF) electrodes, purge gas delivery systems, etc. Some pedestal bases may have one or more large, generally flat surfaces that are designed to come into contact with a semiconductor wafer across its entire underside, while other pedestal bases may be configured to support a semiconductor wafer only near its outer edge, e.g., using spacers that elevate the semiconductor wafer above the remainder of the pedestal base such that there is a gap between the underside of the semiconductor wafer and the portion of the pedestal base underneath it (except, of course, for near the semiconductor wafer edge). Regardless, a pedestal base will generally include one or more wafer support features that define a first reference plane that is generally co-planar or coincident with the underside of a semiconductor wafer supported by the wafer support features. Such wafer support features may include, for example, a single, flat circular area (potentially having one or more grooves or recesses within it) that makes contact with the underside of the semiconductor wafer across most or all of the underside of the semiconductor wafer or a generally flat circular area with a plurality of small minimum-contact-area or low-contact-area features distributed across it (each of which acts as an individual wafer support feature). In some implementations, e.g., pedestal bases that are configured to support a semiconductor wafer such that a gap may exist between the underside of the semiconductor wafer and most of the pedestal base, the pedestal base may include a removable carrier ring that is supported by spacers of the pedestal base at a position that is generally elevated above other portions of the pedestal base; such a carrier ring may include tabs that project radially inward from an interior diameter of the carrier ring and that contact the underside of the semiconductor wafer. The tabs in such an implementation would provide the wafer support surfaces of the pedestal. In alternate pedestal bases that are configured to support a semiconductor wafer such that a gap may exist between the underside of the semiconductor wafer and most of the pedestal base, the pedestal base may simply include spacers that have surfaces that directly contact the semiconductor wafer (without the need for the pedestal base to include a carrier ring) and hold it aloft above the remainder of the pedestal base; such surfaces may act as wafer support surfaces in such implementations.

The systems discussed herein each feature one or more wafer-centering features that collectively have one or more radially inward-facing wafer-centering surfaces. Such wafer-centering surfaces are, at least during wafer-centering operations, positioned such that portions thereof are located between two reference planes defined by the upper and lower surfaces of the semiconductor wafer being centered. Each wafer-centering surface is also positioned radially outward from a target location on which the semiconductor wafer is to be centered by a distance that is greater than half the diameter of the semiconductor wafer. Thus, the one or more radially inward-facing wafer-centering surfaces may generally circumscribe a reference circle that has a diameter larger than that of the semiconductor wafer. In effect, the one or more radially inward-facing wafer-centering surfaces may form a fence or cage that surrounds the semiconductor wafer yet leaves some room for movement between the one or more radially inward-facing wafer-centering surfaces and the semiconductor wafer. The one or more radially inward-facing wafer-centering surfaces may be positioned such that the different between the diameter of the reference circle and the diameter D of the semiconductor wafer is large enough that it exceeds any expected potential off-centeredness in the initial placement of the semiconductor wafer on the pedestal base.

In addition to the one or more radially inward-facing wafer-centering surfaces, the systems discussed herein may also include one or more movement mechanisms associated with a pedestal base that are configured to cause various one or more components or sub-assemblies of such systems to move relative to other components or sub-assemblies. The one or more movement mechanisms may include at least one first movement mechanism that is configured to move one of the pedestal base and the one or more radially inward-facing wafer-centering surfaces associated with that pedestal base at least laterally relative to the other of the pedestal base and the one or more radially inward-facing wafer-centering surfaces associated with that pedestal base. “Lateral” movement, in this context, refers to movement in directions generally parallel to the first reference plane. In most systems, lateral movement will generally be horizontal movement. However, it will be recognized that the systems and techniques discussed herein may also be implemented in contexts in which the first reference plane is non-horizontal, e.g., at a tilt (although the amount of tilt, it will be understood, may be limited so as to avoid gravity-induced slip between the semiconductor wafer and the pedestal base).

Such a system may also include a controller that is configured to control at least the first movement mechanism so as to cause the first movement mechanism to move whichever of the pedestal base and the one or more radially inward-facing wafer-centering surfaces associated with that pedestal base at least laterally relative to the other of the pedestal base and the one or more radially inward-facing wafer-centering surfaces associated with that pedestal base.

A system configured as described above may be controlled so as to perform a wafer-centering operation in which the first movement mechanism is configured to undergo one or more movements that include one or more lateral components. Such movements may be selected so as to cause a target center point of the pedestal base, i.e., a point that is fixed with respect to the pedestal base and that is selected as the location relative to the pedestal base that the center of the wafer is to be centered on, to move towards the reference circle by some amount. In most implementations, the amount may be half the difference between the diameter “d” of the reference circle and the diameter “D” of the semiconductor wafer. It will, of course, be understood that the “half the difference between the diameter “d” of the reference circle and the diameter “D” of the semiconductor wafer” may be inclusive of a small amount of tolerance, e.g., ±150 μm, that still allows for wafer centering that is considered to be within acceptable bounds.

In many implementations, the first movement mechanism may be controlled to perform multiple such movements or to cause the target center point of the pedestal base to follow a path having a particular geometry, e.g., one or more circular paths and/or a spiral path, that stays within a circle having a radius that is half the difference between the diameter of the reference circle and the diameter of the semiconductor wafer (thus constraining such movement as discussed above).

If such movements are performed when the semiconductor wafer is already perfectly centered on the target center point of the pedestal base, the edge of the wafer will, in the ideal state, just come into contact with the one or more radially inward-facing wafer-centering surfaces but will not be moved by such contact. However, if the semiconductor wafer is not perfectly centered on the target center point of the pedestal base prior to such movements being performed, movements that cause the semiconductor wafer to come into contact with one of the one or more radially inward-facing wafer-centering surfaces will generally cause the semiconductor wafer to move radially inward relative to the target center point, thereby causing the semiconductor wafer to become more centered on the target center point. Such movements may be caused to be performed such that multiple points about the circumference of the semiconductor wafer are caused to move towards one of the one or more radially inward-facing wafer-centering surfaces, thereby causing the semiconductor wafer to be nudged towards the target center point until it is eventually centered on the target center point.

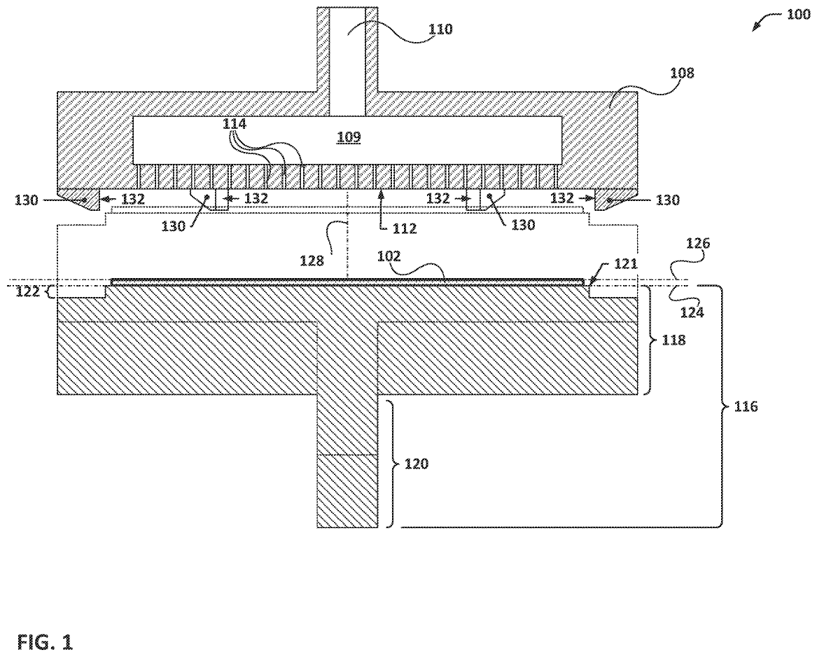

FIG. 1 depicts an example simplified representation of a pedestal, semiconductor wafer, showerhead, and wafer-centering features. The first movement mechanism and semiconductor processing chamber housing discussed above are not shown in FIG. 1, but later Figures provide examples of such.

As can be seen in FIG. 1, a showerhead 108 is provided that includes a gas inlet 110 that may supply one or more processing gases to an interior plenum volume 109 of the showerhead 108. The interior plenum volume 109 may, in turn, be fluidically connected with a plurality of gas distribution ports 114 that exit the underside of the showerhead 108 via a first surface 112 of the showerhead 108. Gas that is flowed into the showerhead 108 via the gas inlet 110 is thus flowed out of the showerhead 108 via the gas distribution ports 114. It is to be understood that the term “showerhead” may be used to refer to any structure that is configured to distribute or deliver processing gas to a wafer during wafer processing operations within a semiconductor processing chamber.

As is also evident in FIG. 1, a plurality of wafer-centering features 130 may extend from the underside of the showerhead 108, projecting downward towards the pedestal base 118. Each wafer-centering feature 130 may have a corresponding radially inward-facing wafer-centering surface 132 that is located at least partially at an elevation that is lower than the first surface 112

The showerhead 108 in the implementation of FIG. 1 may be positioned above a pedestal 116 that includes a pedestal base 118 that is supported by a stem 120. The pedestal base 118 may have a wafer support feature 122. In this example, there is a single wafer support feature 122 that takes the form of a raised, circular platform defined by a circumferential edge 121. The wafer support feature 122 defines a first reference plane 124 that is coincident with the underside of a semiconductor wafer 102 that rests atop the wafer support feature 122. The first reference plane 124 may also define a second reference plane 126 that is parallel to the first reference plane 124 and spaced apart from it by the thickness T of the semiconductor wafer 102 and in a direction towards the showerhead 108.

The pedestal 116 in this example may be movable along an axis 128 that is perpendicular to the first reference plane 124, e.g., to the position shown in dotted outline. As can be seen, the pedestal 116 is movable between a first configuration in which the pedestal base 118 is located as shown in solid lines, e.g., with the first reference plane 124 at least a distance equal to the thickness T of the semiconductor wafer 102 below the wafer-centering features 130, and a second configuration in which the pedestal base 118 is located as shown in dotted outline, e.g., with the first reference plane 124 within a distance equal to the thickness T of the semiconductor wafer 102 of the wafer-centering features 130. As can be seen, in the second configuration, the radially inward-facing wafer-centering surfaces 132 extend into the space between the first reference plane 124 and the second reference plane 126. Thus, if the pedestal 116 is caused to move horizontally when in the second configuration, the edge of the wafer 102 will eventually contact one of the radially inward-facing wafer-centering surfaces 132.

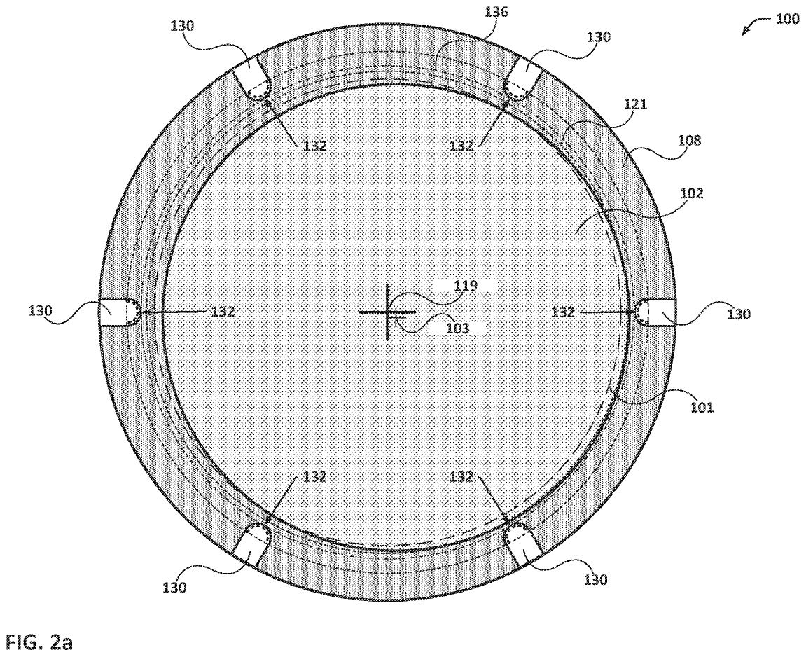

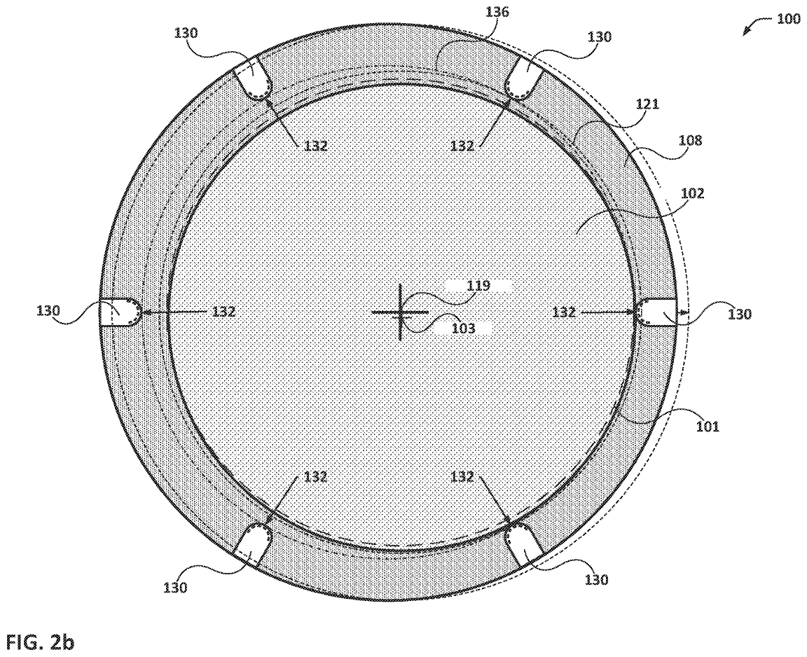

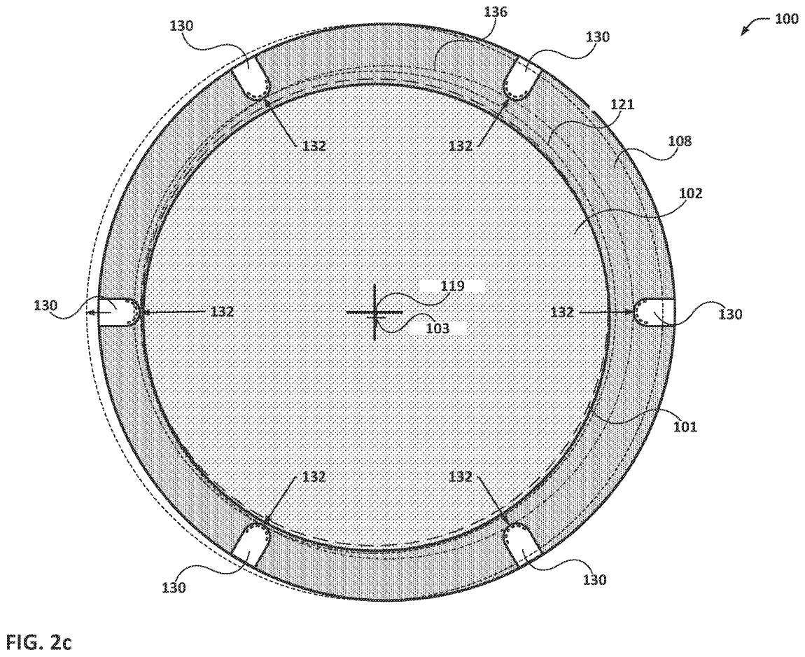

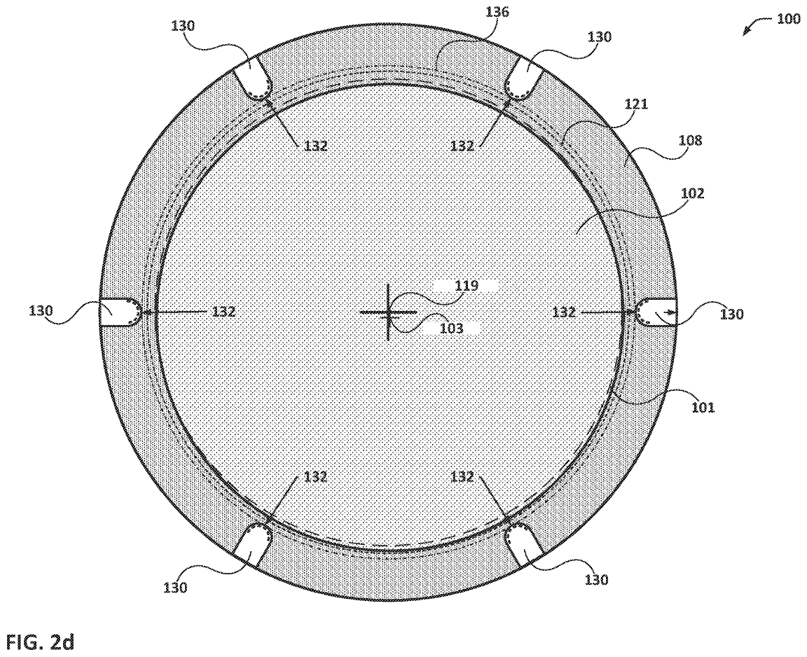

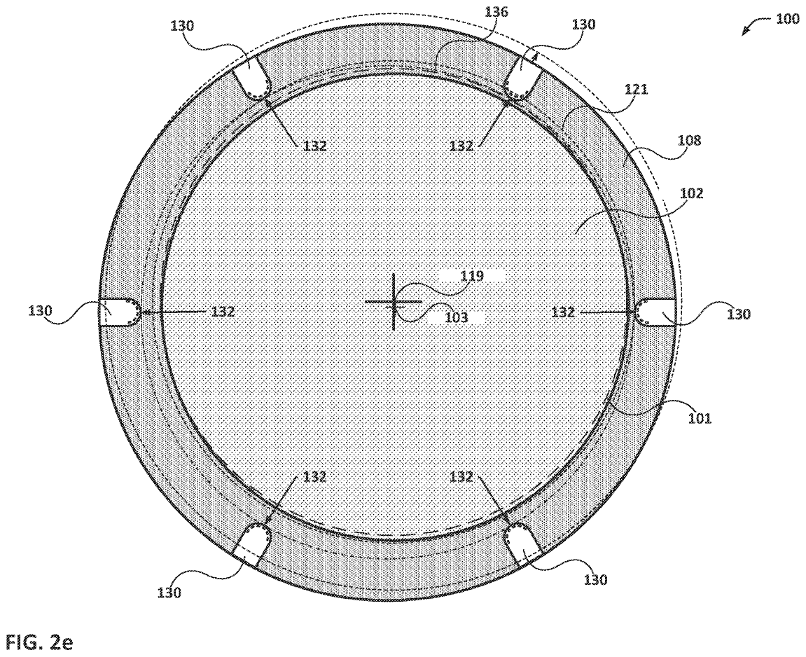

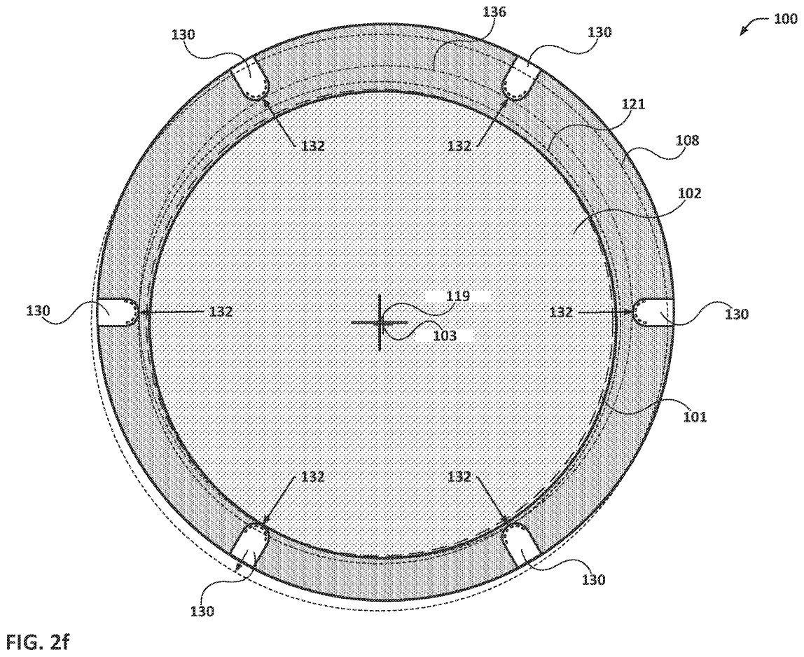

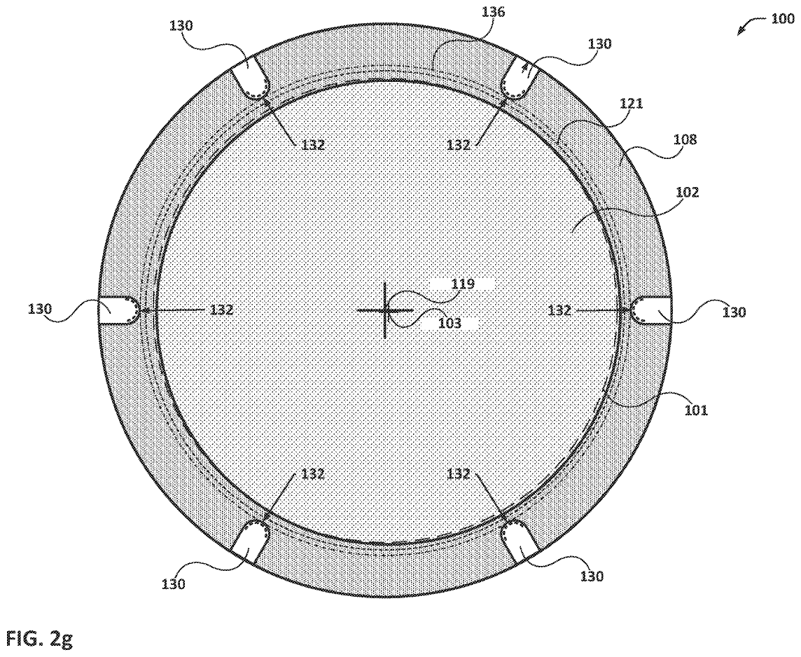

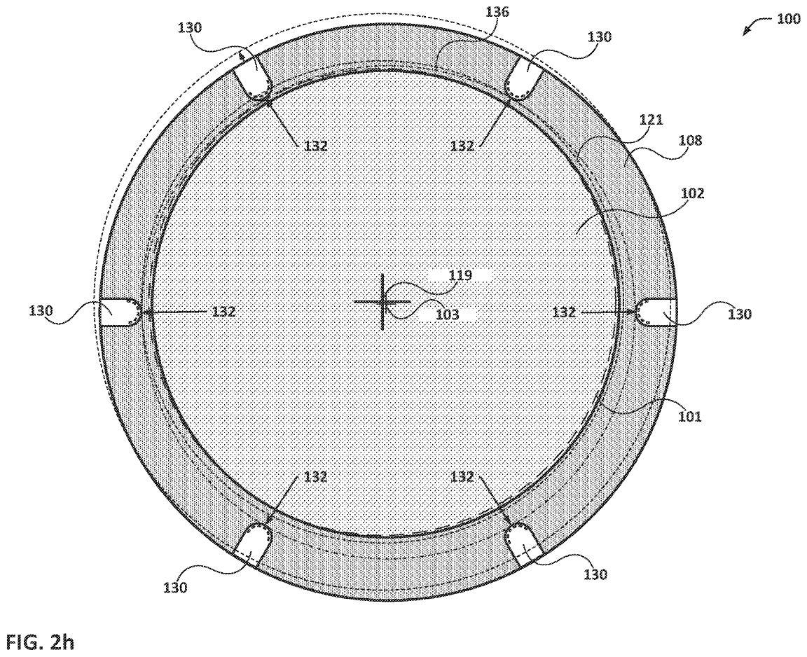

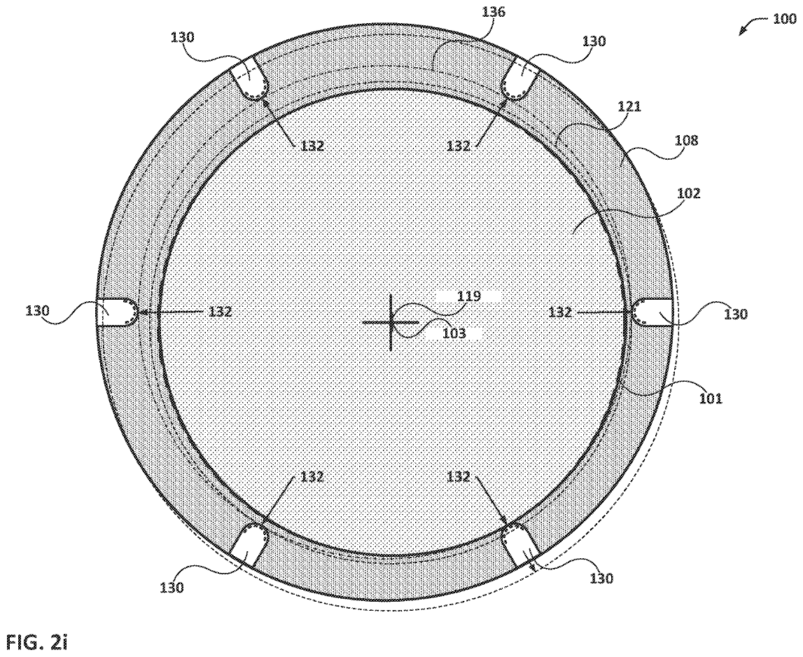

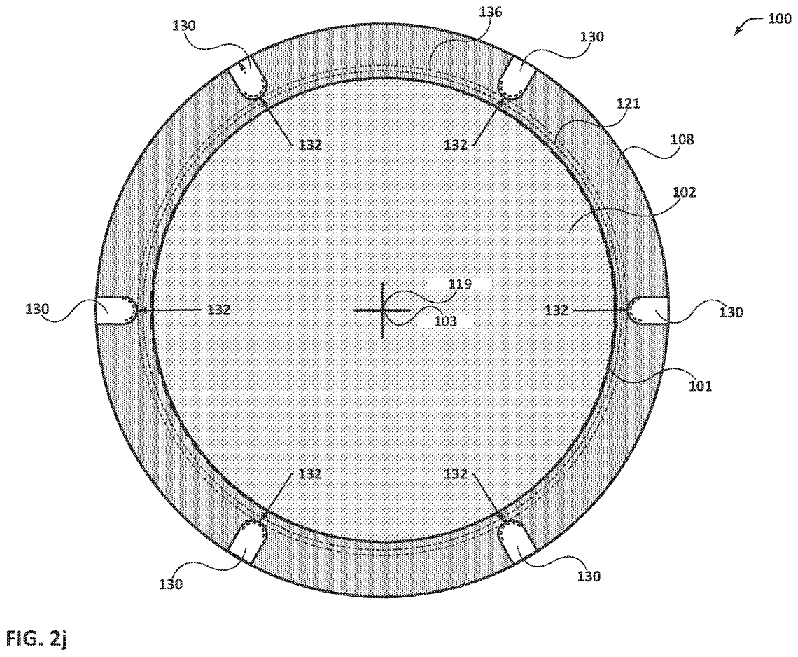

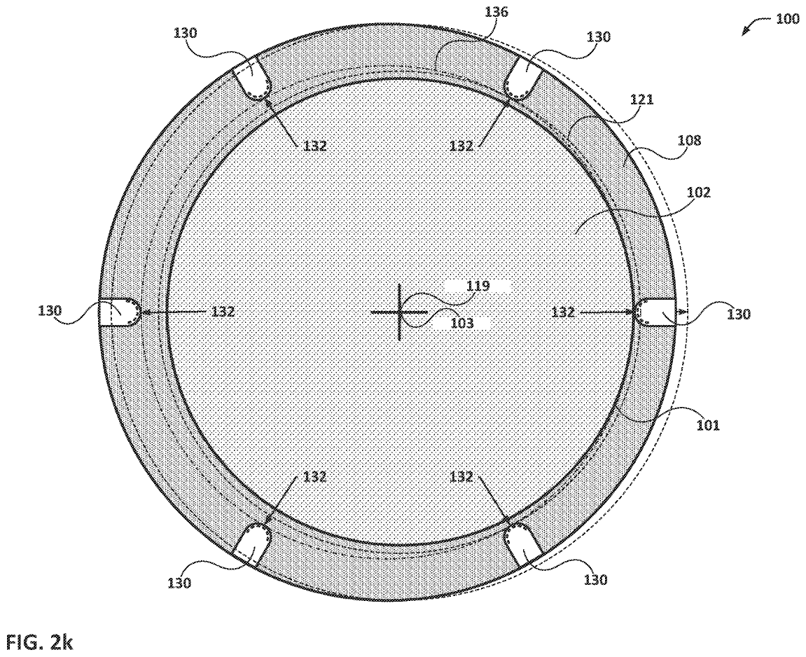

Such movement is described further with respect to FIGS. 2a through 2l, which depict a plan view of the elements shown in FIG. 1 during various phases of a wafer-centering process. The showerhead 108 (minus the gas distribution ports 114), wafer-centering features 130, and semiconductor wafer 102 are shown in solid outline, while the pedestal base 118 is shown in dotted outline. As can be seen in FIG. 2a, the pedestal base 118 is shown in a position that centers it underneath the showerhead 108, as it would be during wafer processing operations. The long-dashed circle represents centered wafer footprint 101, which represents the footprint of the semiconductor wafer 102 when it is perfectly centered on target center point 119 of the pedestal base 118. The wafer 102, however, has a wafer center 103 that is presently off-center from the target center point 119.

As can be seen in FIG. 2a, the radially inward-facing wafer-centering surfaces 132 of the wafer-centering features 130 are arcuate surfaces that, at their furthest radially inward points, circumscribe a reference circle 136, indicated by a dash-dot-dash line. FIGS. 2b through 2l show the pedestal base 118 as it is moved laterally through various locations relative to the showerhead 108 such that the wafer 102 is caused to become centered relative to the pedestal base 118. Reference to the directions of movement in the following discussion use terms like left, right, upwards, downwards to refer to movement relative to the orientation of the page for each Figure.

For example, in FIG. 2b, the pedestal base 118 has been caused to move to the right by a distance equal to half the difference between the diameter of the reference circle 136 and the diameter of the semiconductor wafer 102, as indicated by the arrow at far right. This brings the semiconductor wafer 102 into contact with the right-most radially inward-facing wafer-centering surface 132 for part of the lateral movement of the pedestal base 118, such that the semiconductor wafer 102 is nudged leftwards relative to the pedestal base 118 and closer to the target center point 119.

In FIG. 2c, the pedestal base has been caused to move to the left by the difference between the diameter of the reference circle 136 and the diameter of the semiconductor wafer 102, as indicated by the arrow at far left (this distance is twice the distance moved in FIG. 2b since the pedestal base 118 is first moved back to its home position where it is centered on the showerhead 108, effectively reversing the movement performed in FIG. 2b, before being moved to the location shown in FIG. 2c. As can be seen, the semiconductor wafer 102 approaches, but does not contact, the left-most radially inward-facing wafer-centering surface 132. As such, no relative movement between the semiconductor wafer 102 and the pedestal base 118 occurs during the movement indicated in FIG. 2c.

In FIG. 2d, the pedestal base 118 is caused to return to its home position before being moved, as shown in FIG. 2e, to the upper right along a vector 60° from horizontal (with reference to the page orientation) by half the difference between the diameter of the reference circle 136 and the diameter of the semiconductor wafer 102. As can be seen, the semiconductor wafer 102 approaches, but does not contact, the uppermost radially inward-facing wafer-centering surface 132 on the right. As such, no relative movement between the semiconductor wafer 102 and the pedestal base 118 occurs during the movement indicated in FIG. 2e.

In FIG. 2f, the pedestal base has been caused to move to the lower left by the difference between the diameter of the reference circle 136 and the diameter of the semiconductor wafer 102, as indicated by the arrow at bottom left (this distance is twice the distance moved in FIG. 2e since the pedestal base 118 is first moved back to its home position where it is centered on the showerhead 108, effectively reversing the movement performed in FIG. 2e, before being moved to the location shown in FIG. 2f. This brings the semiconductor wafer 102 into contact with the bottommost radially inward-facing wafer-centering surface 132 on the left for part of the lateral movement of the pedestal base 118, such that the semiconductor wafer 102 is nudged upwards to the right relative to the pedestal base 118 and closer to the target center point 119.

In FIG. 2g, the pedestal base 118 is caused to return to its home position before being moved, as shown in FIG. 2h, to the upper left along a vector 60° from horizontal (with reference to the page orientation) by half the difference between the diameter of the reference circle 136 and the diameter of the semiconductor wafer 102. As can be seen, the semiconductor wafer 102 approaches, but does not contact, the uppermost radially inward-facing wafer-centering surface 132 on the left. As such, no relative movement between the semiconductor wafer 102 and the pedestal base 118 occurs during the movement indicated in FIG. 2h.

In FIG. 2i, the pedestal base has been caused to move to the lower right by the difference between the diameter of the reference circle 136 and the diameter of the semiconductor wafer 102, as indicated by the arrow at bottom right (this distance is twice the distance moved in FIG. 2e since the pedestal base 118 is first moved back to its home position where it is centered on the showerhead 108, effectively reversing the movement performed in FIG. 2h, before being moved to the location shown in FIG. 2i. This brings the semiconductor wafer 102 into contact with the bottommost radially inward-facing wafer-centering surface 132 on the right for part of the lateral movement of the pedestal base 118, such that the semiconductor wafer 102 is nudged upwards to the left relative to the pedestal base 118 and closer to the target center point 119.

In FIG. 2j, the pedestal base 118 is caused to return to its home position. At this point, the pedestal base 118 has been caused to move towards all six of the radially inward-facing wafer-centering surfaces 132 from the home position, thereby nudging the semiconductor wafer 102 much closer to the target center point 119. However, as can be seen, the semiconductor wafer 102 is still somewhat off-center relative to the target center point 119. If further refinement of the centering of the semiconductor wafer 102 is desired, movements such as those described above may be repeated, with each such repetition further nudging the semiconductor wafer 102 closer to the target center point 119 until the wafer is completely centered on the target center point 119.

For example, in FIG. 2k, the pedestal base 118 has been caused to repeat the motion depicted in FIG. 2b, causing the semiconductor wafer 102 to come into contact with the right-most radially inward-facing wafer-centering surface 132 again for part of the lateral movement of the pedestal base 118, such that the semiconductor wafer 102 is nudged leftwards relative to the pedestal base 118 and closer to the target center point 119 again.

In FIG. 2l, the pedestal base 118 is caused to return to its home position. As can be seen, the semiconductor wafer 102 is now completely centered on the target center point 119.

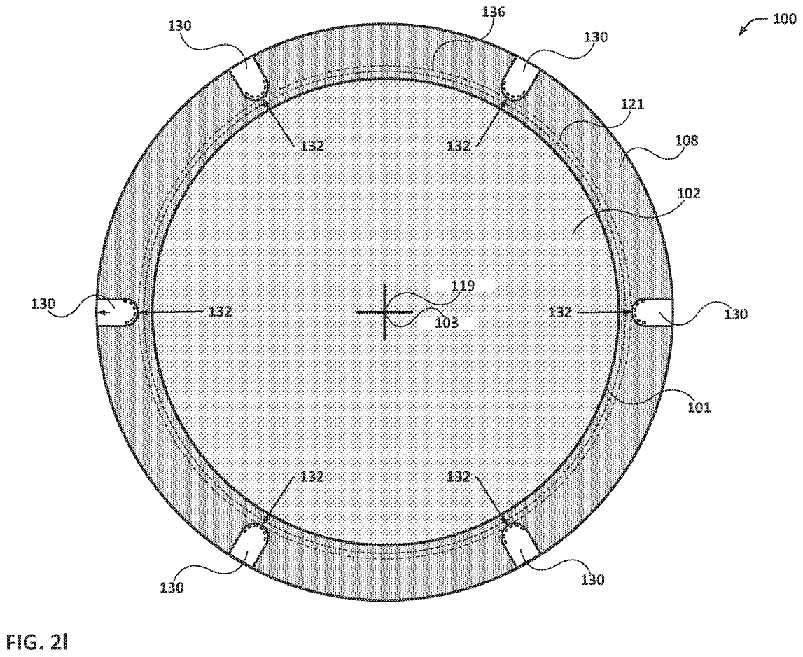

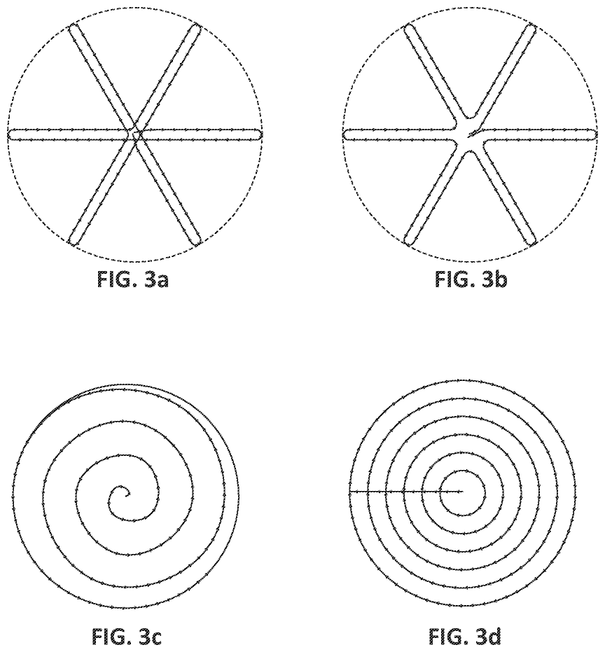

The movement pattern shown in FIGS. 2b through 2l is reproduced in FIG. 3a and generally includes repeated radial movement from the home position to sides of a circle (shown using dashed lines) that is concentric with the reference circle 136 and has a diameter equal to the difference between the diameter of the reference circle 136 and the diameter of the semiconductor wafer 102. As can be seen, the target center point 119 of the pedestal base 118 may be caused to repeatedly travel to one side of the circle from the home position, back through the home position (in the center of the circle), and then to the other side of the circle before returning again to the home position (the radial movement of the target center point 119 is shown as being along spaced-apart paths, but this is simply for ease of understanding—the actual paths followed may all pass through the target center point).

FIG. 3b depicts an alternate path that the pedestal base 118 may be caused to move along. The path of FIG. 3b is similar to that in FIG. 3a, but the target center point may instead be caused to change direction each time it reaches the center of the circle (instead of passing through the center of the circle to the opposite side of the circle).

FIG. 3c depicts another type of path that the pedestal base 118 may be caused to move along. The path indicated in FIG. 3c is a spiral path that spirals outward from the location of the target center point when the pedestal base 118 is in the home position until it reaches a distance that is equal to half the difference between the diameter of the reference circle 136 and the diameter of the semiconductor wafer 102 from that location, at which point the path transitions to a circular or arcuate path that is co-radial with the circle. If such a path is used, the semiconductor wafer 102, if off-center with respect to the target center point, will eventually be caused to contact the radially inward-facing wafer-centering surfaces 132 in sequential fashion around the circumference of the circle, with each such contact nudging the semiconductor wafer closer to the target center point. Such an approach avoids large-scale, single adjustments of the position of the semiconductor wafer 102 relative to the target center point and may thus result in a more precise centering result that does not require repetitions of previously performed movements, as occurred in FIG. 2k.

FIG. 3d depicts yet another example path that may be taken by the pedestal base 118. In the path depicted in FIG. 3d, the pedestal base 118 is caused to follow repeated circular paths, each increasing in diameter relative to the previous one, until the final circular path that is followed by the pedestal base 118 is co-radial with the circle.

It will be understood that the four paths discussed above are but some examples of paths that the pedestal base 118 may be caused to follow in order to center the semiconductor wafer 102 on the target center point 119. It will also be understood, as will be evident from further examples discussed below, that the wafer-centering techniques discussed above may also be implemented in similar form, but with the wafer-centering features 130 caused to move relative to the pedestal base 118. For example, the showerhead 108, with the wafer-centering features 130, may be caused to move relative to pedestal base 118 in order to cause the semiconductor wafer 102 to be nudged towards the target center point 119. In such cases, the movement of the wafer-centering features 130 relative to the pedestal base 118 may be reversed from the movements of the pedestal base 118 in the examples discussed above. For example, the wafer-centering features 130 may be caused to collectively move so as to follow a path that spirals inward, effectively the reverse of the path from FIG. 3c.

It will be understood that the movement paths that are described above and shown in FIGS. 3a through 3d may be quite small in actual practice, e.g., fitting within a circular area of just a few millimeters or even less, e.g., 1 mm or less. Most wafer placement systems are capable of placing a semiconductor wafer within a few hundred microns of its intended position, so the movements of the pedestal base relative to the wafer-centering features that may be needed to center the wafer on the target center point may be correspondingly quite small.

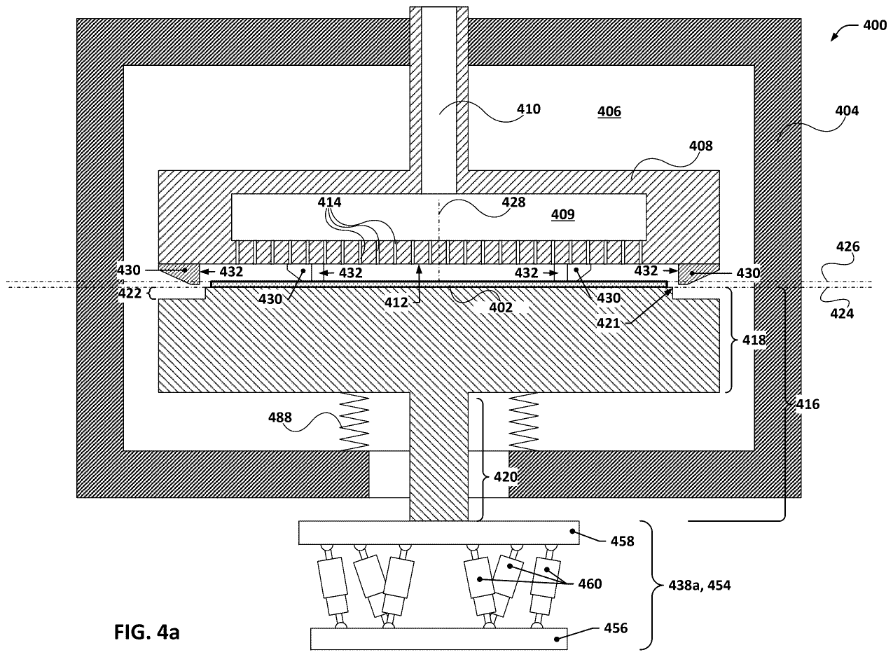

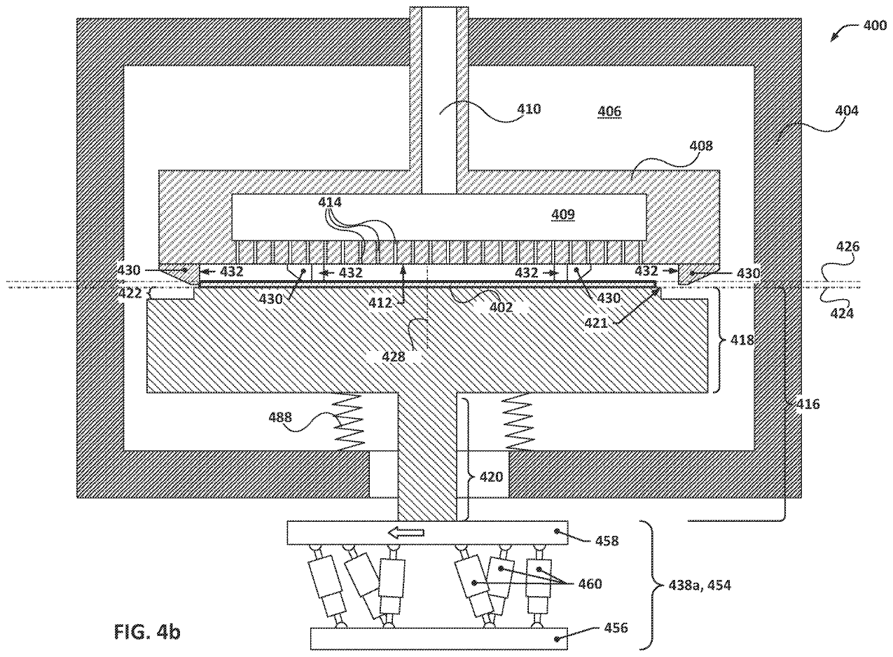

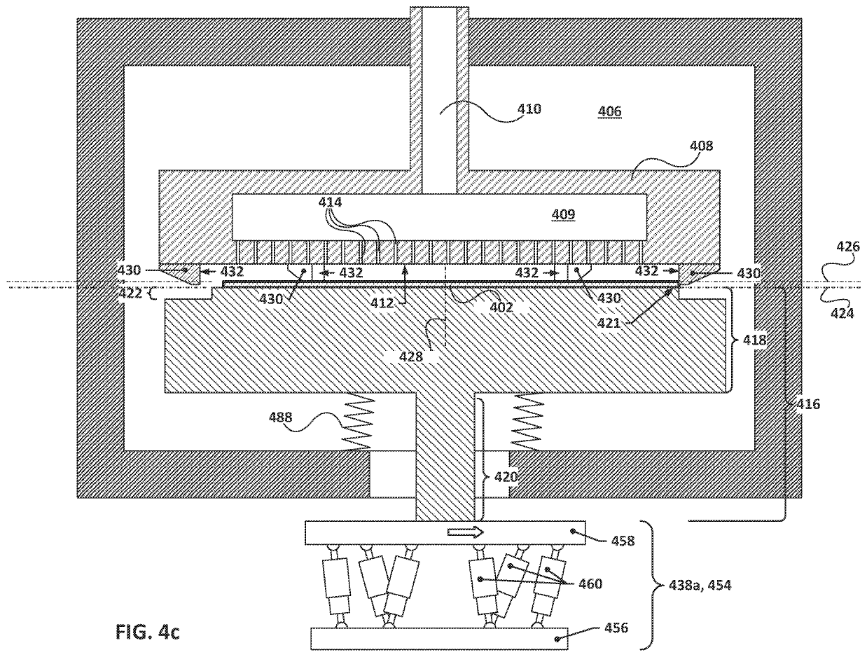

The above discussion has focused on how a pedestal base may be moved laterally so as to cause a semiconductor wafer supported thereon to be nudged so as to be centered on a target center point, but the examples above have not discussed example movement mechanisms that may be used to provide such movements. The following discussion examines several different types of movement mechanisms that are depicted in FIGS. 4a through 6.

FIGS. 4a through 4c depict an example semiconductor processing tool 400 that includes a semiconductor processing chamber 404. The semiconductor processing chamber 404 may have an interior volume 406 that is bounded by walls of the semiconductor processing chamber 404.

The semiconductor processing chamber 404 may house, at least partially, a showerhead 408 within the interior volume 406. The showerhead 408 may include a gas inlet 410 that may be used to provide one or more processing gases to an interior plenum volume 409 of the showerhead 408. Such processing gases may then be flowed out of the interior plenum volume 409 via a plurality of gas distribution ports 414 that are distributed across a first surface 412 of the showerhead 408. As with the showerhead 108, the showerhead 408 has a plurality of wafer-centering features 430 that are fixed with respect to the showerhead 408.

The interior volume 406 may also house within it, at least partially, a pedestal 416. The pedestal 416 may include a pedestal base 418 that is supported by a stem 420. The stem 420, in this example, extends through an aperture in the floor of the semiconductor processing chamber 404 and connects with a first movement mechanism 438a. A bellows seal 488, e.g., a metal bellows seal, may be connected with the pedestal base 418 and the semiconductor processing chamber 404 in order to prevent processing gases from leaking out of the semiconductor processing chamber 404 while still allowing for both vertical and lateral movement of the pedestal 416 relative to the semiconductor processing chamber 404.

The first movement mechanism 438a is, in this case, a hexapod mechanism 454. The hexapod mechanism 454 may have a base mount 456 and a movable mount 458, as well as six independently controllable linear actuators 460 that connect the base mount 456 with the movable mount 458 to provide a device generally referred to as a “Stewart platform.” The base mount 456 of the hexapod mechanism 454 may be fixedly mounted with respect to the semiconductor processing chamber 404, or at least mounted such that it may be held motionless with respect to the semiconductor processing chamber 404, while the movable mount 458 of the hexapod mechanism 454 supports the pedestal 416 that is used to support a semiconductor wafer 402 within the semiconductor processing chamber 404.

Stewart platforms are typically used in applications where six degrees of freedom are required over a relatively large range of motion, such as flight simulators, radio telescopes, spacecraft docking systems, etc. Such Stewart platform systems may, for example, frequently be designed to be able to rotate their movable mounts by as much as 45° to 60° of tilt in any direction and are often able to translate their movable mounts in all directions by significant distances. Hexapod mechanisms used in semiconductor processing tools, such as the semiconductor processing tool 100, may be configured to provide smaller amounts of movement but with greater precision.

By supporting the pedestal 416 on the movable mount 458 of the hexapod mechanism 454, the pedestal 416 may be caused to move laterally and/or vertically and/or tilt or rotate, simultaneously, if desired. Thus, the lateral movements of the pedestal base 118 discussed above with respect to FIGS. 2a through 2l may be produced, for example, in the example semiconductor processing chamber 404 by controlling the hexapod mechanism 454 to cause the movable mount 458 to perform pure translational motion without any vertical movement or rotation of the semiconductor wafer 402. In effect, the hexapod mechanism 454 may be controlled to move the movable mount 458 along any desired two-dimensional path in order to cause the semiconductor wafer 402 to be nudged inward towards the target center point by radially inward-facing wafer-centering surfaces 432 of wafer-centering features 430. The hexapod mechanism 454 may also be controlled so as to cause the pedestal base 418 to move up and down vertically, e.g., such that a vertical gap exists between the semiconductor wafer 402 and the lowest portions of the wafer-centering features 430 or such that the lowest portions of the wafer-centering features 430 are within a thickness T of a first reference plane 424 (which is coincident or coplanar with the underside of the semiconductor wafer 402). This allows the semiconductor wafer 402 to be effectively caged or trapped between the pedestal base 418, the showerhead 408, and the wafer-centering features 430 in some instances, but then released such that the semiconductor wafer can be moved onto or off of the pedestal 416 without colliding with the wafer-centering features 430.

FIGS. 4b and 4c depict the hexapod mechanism 454 having been actuated so as to cause the movable mount 458 to move laterally left and laterally right, respectively, so as to bring the semiconductor wafer 402 into contact with the wafer-centering features 430 on either side of the showerhead 408. It will be appreciated that the hexapod mechanism 454 may also be controlled so as to bring the semiconductor wafer 402 into contact with any of the other wafer-centering features 430 as well.

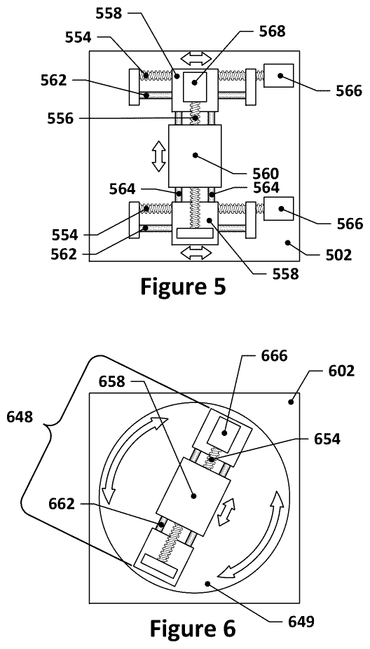

FIG. 5 depicts another example movement mechanism that may be used as the first movement mechanism. The movement mechanism of FIG. 5 is an XY stage that features first guides 562 that are fixedly mounted with respect to a base mount 556. A first stage or stages 558 may be slidably mounted to the first guides 562 and may be actuated using first motor or motors 566 that may drive first linear screw or screws 554 (which may collectively form a first linear translation mechanism), thereby causing the first stage or stages 558 to translate linearly in the left-right direction with respect to FIG. 5. The first stage or stages 558 may similarly support a second guide or guides 564 that may slidably support a second stage 560. The second stage 560 may be caused to translate linearly along the second guides 564 through actuation of second motor 568, which may drive a second linear screw 556 (which may collectively form a second linear translation mechanism) that causes the second stage 560 to travel along the second guides 564. By driving both the first motor(s) 566 and the second motor(s) 568 at different speeds and/or amounts, e.g., responsive to signals received from a controller, the second stage 560—and a pedestal supported thereby—may be caused to move along any desired path, much in the same manner as the pedestal 416 of FIGS. 4a through 4c. In some implementations, the first stage(s) 558 may translate along first axes that are orthogonal to second axes that the second stage is configured to translate along.

FIG. 6 depicts an R-theta mechanism that may be used for the first movement mechanism in some implementations. In the R-theta mechanism, a linear translation mechanism 648 may be provided that features guides 662 that are fixedly mounted with respect to a rotatable portion 649. The rotatable portion 649 may be rotatably connected with a base portion 602 and may be controllable, e.g., via an electric motor, such that the rotatable portion 649 (and thus the guides 662 and other equipment that may be supported thereby) may be caused to rotate about a rotational axis relative to the base portion 602. The rotatable portion 649 may support a linear translation mechanism 648 that includes a first portion that is fixedly mounted with respect to the rotatable portion 649 and a second portion 658 that is slidably mounted to the guides 662 such that it can translate along the guides 662, e.g., along a radial axis. The guides 662 may be any suitable bearing surface that may guide the motion of the second portion 658, e.g., round steel bars. The stem of the pedestal may be mounted to the second portion 658. The linear translation mechanism may also include a motor 666 that, responsive to inputs received from a controller, may rotate a linear screw 654 that may, in passing through a threaded nut that is fixed with respect to the second portion 658, drive motion of the second portion 658 along the guides 662, as indicated by the double-ended arrow shown in FIG. 6. As with the XY stage of FIGS. 4a through 4c, the R-theta mechanism may be used to cause the pedestal supported thereby to move so as to follow any desired path (within the movement range of the R-theta mechanism.

These are only some of the example movement mechanisms that may be used to provide for relative lateral movement between a pedestal base and one or more wafer-centering features. It will be understood that any suitable mechanism may be used as the first movement mechanism, and the present disclosure is not limited to just the three examples discussed above.

As alluded to earlier, the first movement mechanism need not always be configured to move the pedestal base relative to the wafer-centering features; in some implementations, the first movement mechanism may instead be configured to move the wafer-centering features relative to the pedestal base.

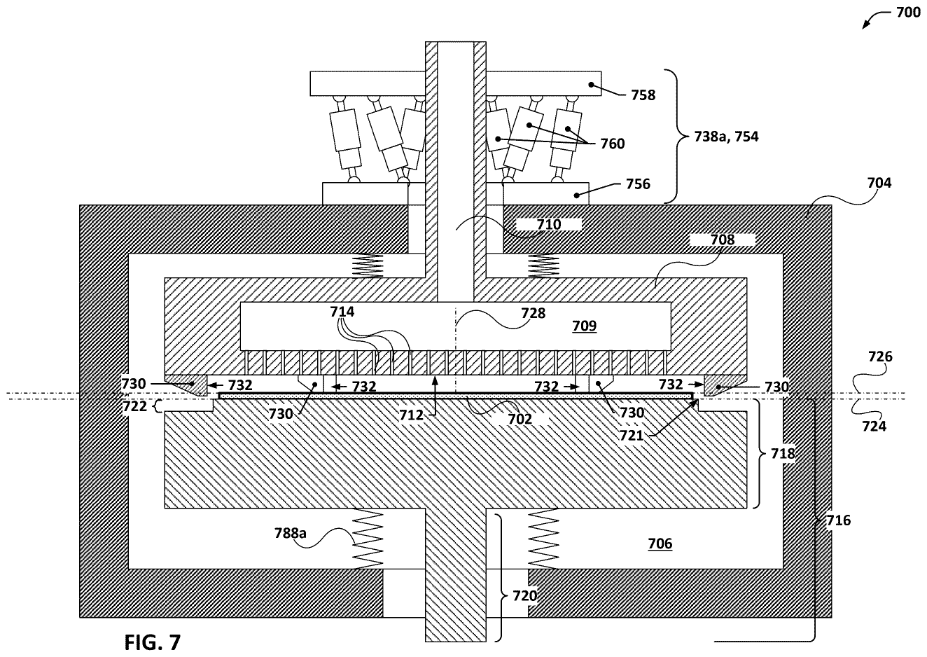

FIG. 7 depicts an example of a semiconductor processing tool that is configured to provide for post-placement wafer centering using a movable showerhead. As shown in FIG. 7, a semiconductor processing tool 700 is provided that includes a showerhead that includes a semiconductor processing chamber 704. The semiconductor processing chamber 704 may have an interior volume 706 that is bounded by walls of the semiconductor processing chamber 704.

The semiconductor processing chamber 704 may house, at least partially, a showerhead 708 within the interior volume 706. The showerhead 708 may include a gas inlet 710 that may be used to provide one or more processing gases to an interior plenum volume 709 of the showerhead 708. Such processing gases may then be flowed out of the interior plenum volume 709 via a plurality of gas distribution ports 714 that are distributed across a first surface 712 of the showerhead 708. As with the showerheads 108 and 408, the showerhead 708 has a plurality of wafer-centering features 730 that are fixed in space with respect to the showerhead 708.

The interior volume 706 may also house within it, at least partially, a pedestal 716. The pedestal 716 may include a pedestal base 718 that is supported by a stem 720. The stem 720, in this example, extends through an aperture in the floor of the semiconductor processing chamber 704 and may, in some implementations, be supported by a movement mechanism (not shown) that may allow the pedestal 716 to be moved up and down, for example. A semiconductor wafer 702 may be supported by the pedestal base 718. A bellows seal 788a, e.g., a metal bellows seal, may be connected with the pedestal base 718 and the semiconductor processing chamber 704 in order to prevent processing gases from leaking out of the semiconductor processing chamber 704 while still allowing for vertical movement of the pedestal 716 relative to the semiconductor processing chamber 704.

The semiconductor processing tool 700, similar to the semiconductor processing tool 400, includes a first movement mechanism 738a that is, in this example, a hexapod mechanism 754. The hexapod mechanism 754 may have a base mount 756 and a movable mount 758, as well as six independently controllable linear actuators 760 that connect the base mount 756 with the movable mount 758 to provide a Stewart platform. The base mount 756 of the hexapod mechanism 754 may be fixedly mounted with respect to the semiconductor processing chamber 704, or at least mounted such that it may be held motionless with respect to the semiconductor processing chamber 704. However, in contrast to the semiconductor processing tool 400, the hexapod mechanism 754 is mounted to the top of the semiconductor processing chamber and the movable mount 758 of the hexapod mechanism 754 supports the showerhead 708 such that the showerhead 708, with the wafer-centering features 730, may be moved laterally relative to the pedestal base 718 in much the same manner as the pedestal base 418 may be moved laterally relative to the showerhead 408 and the wafer-centering features 430 of the example in FIGS. 4a through 4c.

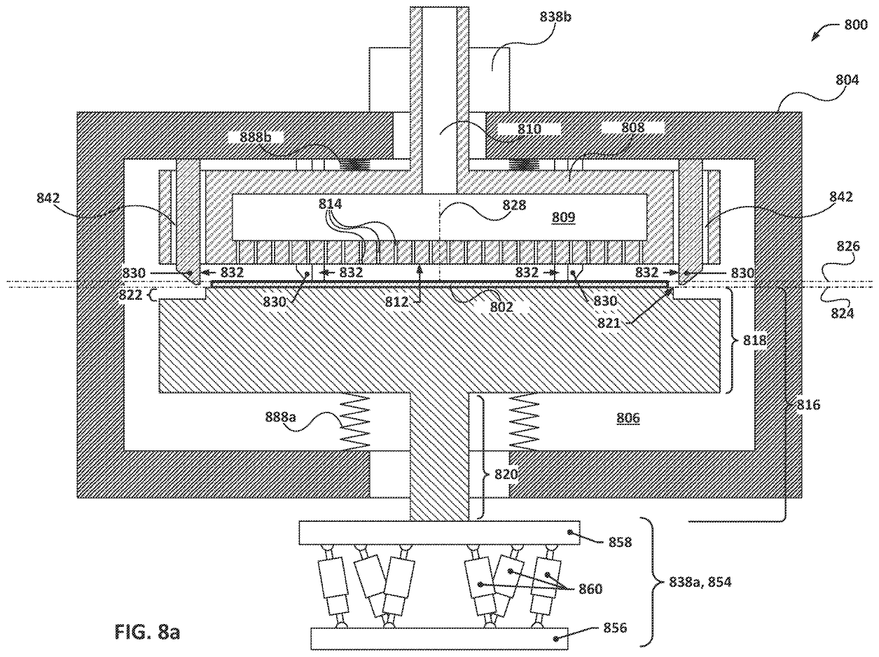

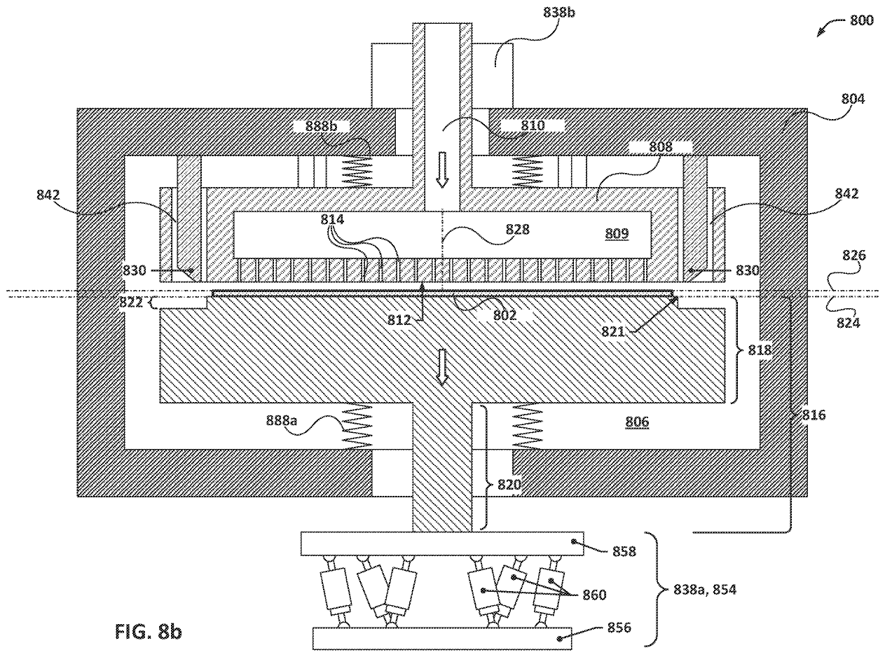

It will also be appreciated that the first movement mechanism of FIG. 7 may be a different type of movement mechanism, such as an XY stage or an R-theta mechanism. Various further example implementations are discussed below with reference to FIGS. 8a through 12b, showing different configurations of wafer-centering features. It will be appreciated that while each of these further examples depicts first movement mechanisms that are hexapod mechanisms, alternative movement mechanisms may be used, as discussed above, in place of the hexapod mechanisms. It will also be noted that the implementations of FIGS. 8a through 12b share many similarities with the examples of FIGS. 4a through 4c and FIG. 7. For the sake of brevity, structures in FIGS. 8a through 12b that are similar to structures in FIGS. 4a through 4c and FIG. 7 will not be described repeatedly below. Such structures, which may be indicated in FIGS. 8a through 12b using callouts with the same last two digits as the callouts used for those structures in FIGS. 4a through 4c and FIG. 7, may be assumed to be the same as those structures in FIGS. 4a through 4c and FIG. 7 unless the discussion below indicates otherwise. Furthermore, the discussion of such structures with reference to FIGS. 4a through 4c and FIG. 7 will be understood to be equally applicable to the structures in FIGS. 8a through 12b that have callouts that share the same last two digits as similar structures in FIGS. 4a through 4c and FIG. 7.

In all of the examples discussed thus far, the wafer-centering features have been fixed in space with respect to the showerhead, e.g., protruding downward from the underside of the showerhead. FIGS. 8a and 8b depict an example semiconductor processing tool 800 in which the wafer-centering features 830 are fixed in space with respect to the semiconductor processing chamber 804, with both the pedestal 816 and the showerhead 808 configured to be movable at least along the axis 828, and with the pedestal base 818 also laterally movable relative to the semiconductor processing chamber 804. For example, the pedestal base 818 may be supported by a first movement mechanism 838a, e.g., a hexapod mechanism 854, that is controllable to move the pedestal 816 (and the pedestal base 818) laterally and/or vertically. Similarly, the showerhead 808 may be connected with a second movement mechanism 838b that may, for example, be a linear actuator or other device that may be controlled so as to cause the showerhead 808 to move up and down relative to the semiconductor processing chamber 804.

As can be seen, the wafer-centering features 830 are, in effect, long posts that extend downward from the ceiling or lid of the semiconductor processing chamber 804 and through pass-through apertures 842 in the showerhead 808. The pass-through apertures 842 may be sized large enough that there is a clearance gap that extends around each wafer-centering feature between the side walls of the pass-through apertures 842 and the portions of the wafer-centering features 830 that are located within the pass-through apertures 842. This clearance gap may be sized such that there is no contact between the wafer-centering features 830 and the showerhead 808 when the showerhead 808 is caused to move along the axis 828, e.g., through operation of second movement mechanism 838b. In some implementations, this gap may be sized to be smaller than the thickness of a plasma sheath, e.g., 1 mm to 2 mm, of a plasma that may be generated within the semiconductor processing chamber when performing wafer processing operations. This may reduce the chance that a plasma may be initiated within the pass-through apertures 842, thereby potentially causing arcing and the generation of particulates that may contaminate the semiconductor wafer 802. It will also be appreciated that the pass-through apertures 842 may alternatively take the form of radial notches in the exterior surface of the pedestal base plate, i.e., the wafer-centering features 830 may be visible throughout the thickness of the pedestal base 818 when viewing the pedestal base 818 from a direction perpendicular to the axis 828. This is true for other similar examples in which pass-through apertures are used, such as examples discussed later below.

FIGS. 8a and 8b depict the semiconductor processing tool 800 when the showerhead 808 and the pedestal base 818 are in various configurations. For example, in FIG. 8a, the showerhead 808 has been raised to a first configuration relative to the semiconductor processing chamber 804 such that first ends of the wafer-centering features 830 protrude out past the first surface 812 of the showerhead 808 and towards the pedestal base 818. The showerhead 808 may also be moved downward into a second configuration, as shown in FIG. 8b, in which the first ends of the wafer-centering features 830 either do not extend past the first surface 812 of the showerhead 808 or extend past the first surface 812 to a lesser extent than in the first configuration.

Similarly, the pedestal base 818 has, in FIG. 8a, been moved into a third configuration relative to the semiconductor processing chamber 804 in which the first reference plane 824 is within a distance T, equal to the thickness of the semiconductor wafer 802, of the first ends of the wafer-centering features 830. It will be appreciated that while the first ends of the wafer-centering features 830 of FIG. 8a are shown as extending into, but not through, the space between the first reference plane 824 and the second reference plane 826, the first ends of the wafer-centering features 830 may also extend past the first reference plane 824 (for example, if the wafer support feature 822 has a diameter smaller than the diameter of the semiconductor wafer 802). In such configurations, portions of the first ends of the wafer-centering features 830 may still be within the thickness T of the semiconductor wafer 802 of the first reference plane 824 even if other portions thereof are further from it.

In FIG. 8b, the pedestal base 818 has been moved downward into a fourth configuration in which the first reference plane 824 is positioned more than the thickness T beneath the first ends of the wafer-centering features 830.

When the showerhead 808 is in the first configuration and the pedestal base 818 is in the third configuration, the semiconductor wafer 802 may be effectively caged in between the first surface 812 and the wafer support feature 822, as well as within a circular region having the same size, shape, and location as the first reference circle. This allows the semiconductor wafer 802 to be centered relative to the pedestal base 818 through lateral movement of the pedestal base 818 relative to the semiconductor processing chamber 804, e.g., as may be provided by the first movement mechanism 838a.

The showerhead 808 may be moved into the second configuration in order to “retract” the wafer-centering features 830 into the showerhead 808 at least partially, thereby reducing the potential for the wafer-centering features to serve as potential sources of anomalies within the semiconductor processing chamber 804 that may result in decreased wafer processing uniformity. The pedestal base 818 may similarly be caused to move into the fourth configuration to, for example, allow for the showerhead 808 to be lowered such that the first surface 812 is lowered to an elevation below the elevation that the second reference plane 826 was at when the pedestal base 818 was in the third configuration. The pedestal base 818 would, in such a case, need to move downward to make room for the downward movement of the showerhead 808. The pedestal base 818 may also be caused to move into the fourth configuration to allow the semiconductor wafer 802 to be inserted into or withdrawn from the space between the showerhead 808 and the wafer support feature 822, e.g., as would be the case when a wafer-handling robot is caused to place the semiconductor wafer 802 on the pedestal base 818. If the pedestal base 818 is not lowered in such a fashion, then any attempt to move the semiconductor wafer 802 laterally with respect to the semiconductor processing chamber will result in the semiconductor wafer 802 colliding with one or more of the wafer-centering features.

The semiconductor processing chamber 804 may also include within it bellows seals 888a and 888b. The bellows seals 888a and 888b may be configured to provide flexible sealing elements between the pedestal base 818 and the semiconductor processing chamber 804 and the showerhead 808 and the semiconductor processing chamber 804. The bellows seals 888a and 888b may, for example, be metal bellows seals, e.g., made of stainless steel.

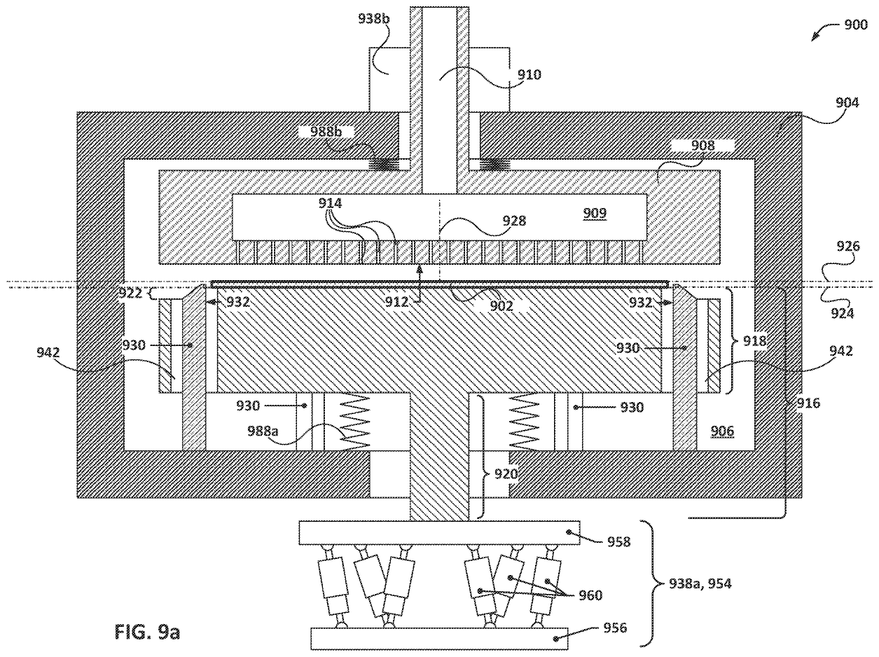

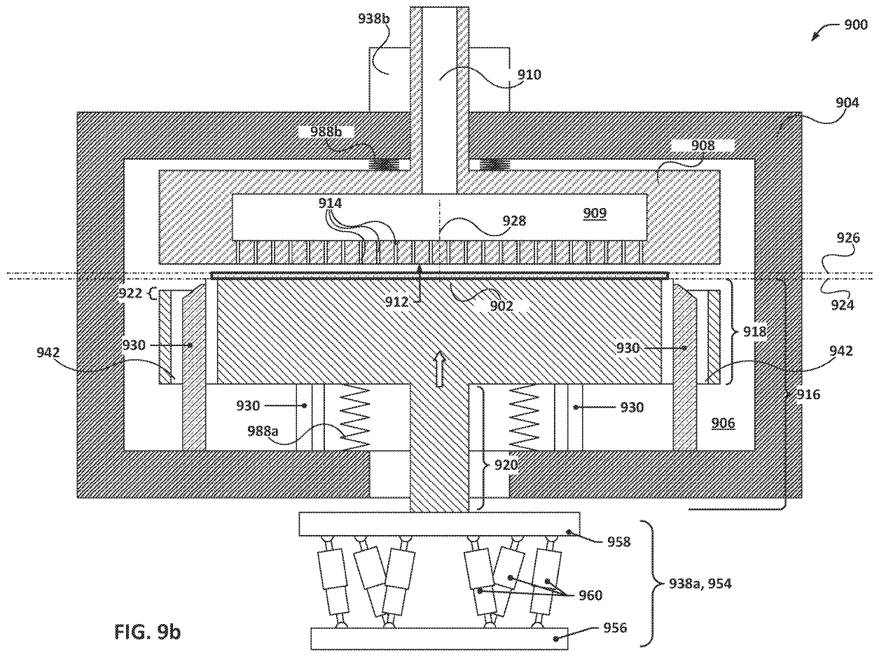

FIGS. 9a and 9b depict a semiconductor processing tool 900 that is similar to the semiconductor processing tool 800 in many respects. However, in the semiconductor processing tool 900, the wafer-centering features 930 are instead fixedly connected with a structure underneath the pedestal base 918 instead of above the showerhead 908. Thus, the wafer-centering features 930 extend upward from the floor or base of the semiconductor processing chamber 904 (or some other structure that is positioned beneath the pedestal base 918 and fixed in position relative to the semiconductor processing chamber 904) and through pass-through apertures 942 in the pedestal base 918. The pass-through apertures 942 may be sized large enough that there is a clearance gap that extends around each wafer-centering feature between the side walls of the pass-through apertures 942 and the portions of the wafer-centering features 930 that are located within the pass-through apertures 942. This clearance gap may be sized such that there is no contact between the wafer-centering features 930 and the showerhead 908 when the showerhead 908 is caused to move along the axis 928, e.g., through operation of second movement mechanism 938b. The clearance gap may also be sized to be larger than half the difference between the diameter of the semiconductor wafer 902 and the reference circle that is defined by the radially inward-facing wafer-centering surfaces 932 of the wafer-centering features 930, thereby allowing sufficient clearance between the sidewalls of the pass-through apertures 942 and the portions of the wafer-centering features 930 that no contact occurs between the wafer-centering features 930 and the sidewalls of the pass-through apertures 942 during lateral movement of the pedestal base 918 relative to the semiconductor processing chamber 904 and the wafer-centering features 930 during wafer-centering operations.

In some implementations, the clearance gap may also be sized to be smaller than the thickness of a plasma sheath, e.g., 1 mm to 2 mm, of a plasma that may be generated within the semiconductor processing chamber when performing wafer processing operations. This may reduce the chance that a plasma may be initiated within the pass-through apertures 942, thereby potentially causing arcing and the generation of particulates that may contaminate the semiconductor wafer 902. It will be understood that such small clearance gaps may still allow sufficient clearance to accommodate wafer-centering movements of the pedestal base 918 relative to the semiconductor processing chamber 904, as the amount of centering correction for the semiconductor wafer 902 that may be needed in many cases may be on the order of a few hundred microns, e.g., such that the difference between the diameter of the semiconductor wafer 902 and the reference circle that is defined by the radially inward-facing wafer-centering surfaces 932 of the wafer-centering features 930 can be on the order of one to two millimeters or less.

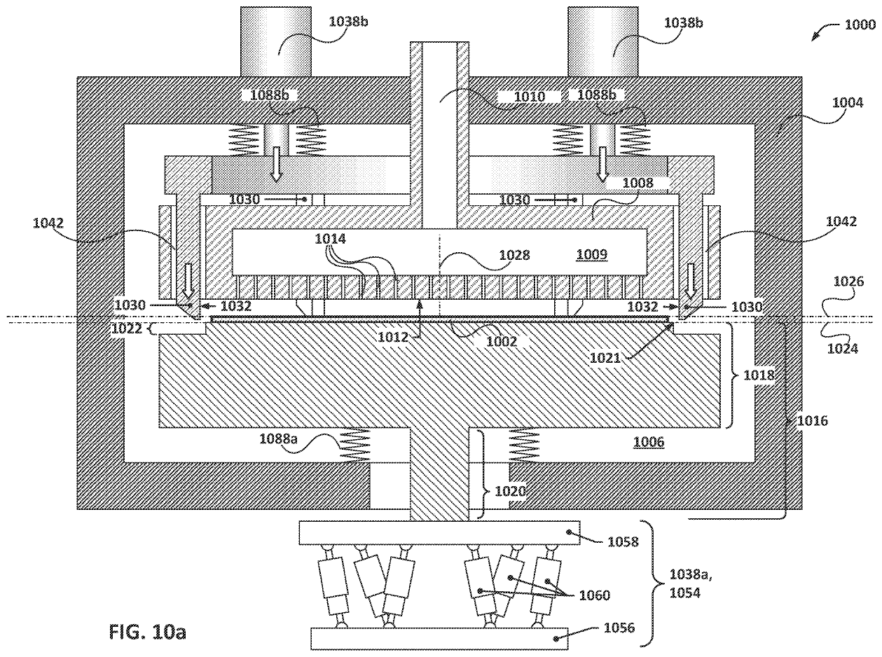

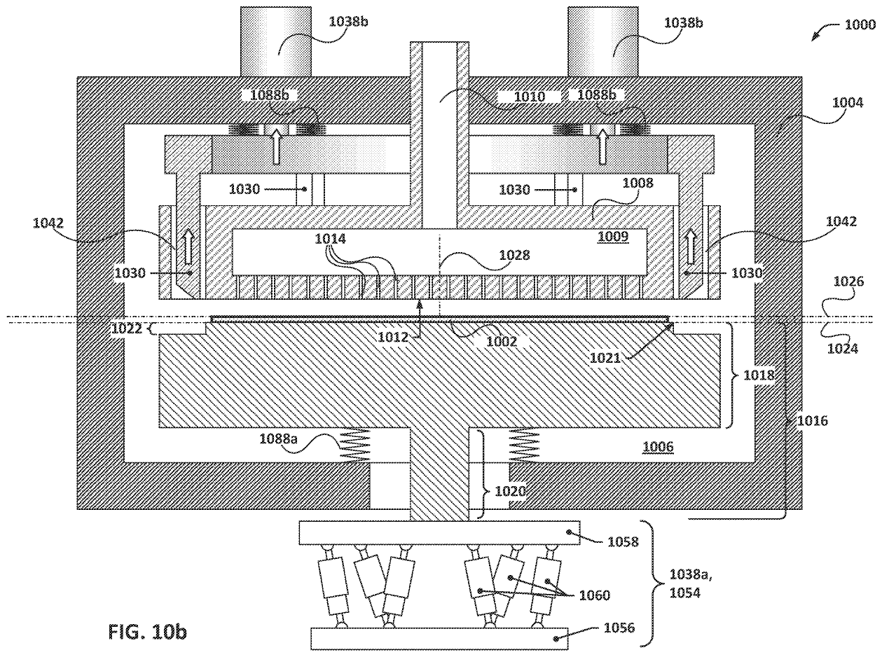

FIGS. 10a and 10b depict an example semiconductor processing tool in which the wafer-centering features are not fixed with respect to the semiconductor processing chamber or showerhead. As can be seen in FIG. 10a, the semiconductor processing chamber 1004 features a pedestal 1016 that is connected with a first movement mechanism 1038a and is configured to be laterally movable relative to the semiconductor processing chamber 1004. For example, the pedestal base 1018 may be supported by the stem 1020 connected with the first movement mechanism 1038a, e.g., a hexapod mechanism 1054, that is controllable to move the pedestal 1016 (and the pedestal base 1018) laterally and/or vertically relative to the semiconductor processing chamber 1004.

As can also be seen, wafer-centering features 1030 are provided that are similar to the wafer-centering features 830 of FIGS. 8a and 8b, except that the wafer-centering features 1030 are connected with one or more second movement mechanisms 1038b, e.g., linear or other actuators, that are configured to be able to move the wafer-centering features 1030 along the axis 1028. The wafer-centering features 1030 are, in this example, long posts that extend downward from a ring-like support structure that encircles a stem of the showerhead 1008 and is connected with the second movement mechanism 1038b. The wafer-centering features 1030 may extend downward from the support structure and through pass-through apertures 1042 through the showerhead 1008.

The pass-through apertures 1042 may be sized large enough that there is a clearance gap that extends around each wafer-centering feature between the side walls of the pass-through apertures 1042 and the portions of the wafer-centering features 1030 that are located within the pass-through apertures 1042. As in previous examples discussed herein, the clearance gap may be sized such that there is no contact between the wafer-centering features 1030 and the showerhead 1008 when the wafer-centering features 1030 are caused to move along the axis 1028, e.g., through operation of second movement mechanism 1038b, relative to the semiconductor processing chamber 1004. As with earlier examples discussed herein, in some implementations, this gap may be sized to be smaller than the thickness of a plasma sheath, e.g., 1 mm to 2 mm, of a plasma that may be generated within the semiconductor processing chamber 1004 when performing wafer processing operations. This may reduce the chance that a plasma may be initiated within the pass-through apertures 1042, thereby potentially causing arcing and the generation of particulates that may contaminate the semiconductor wafer 1002.

FIGS. 10a and 10b depict the semiconductor processing tool 1000 when the wafer-centering features 1030 and the pedestal base 1018 are in various configurations. For example, in FIG. 10a, the second movement mechanism 1038b, e.g., a linear translation mechanism, has been actuated into a first position. The second movement mechanism 1038b, when in the first position, causes the wafer-centering features 1030 to be lowered to a first configuration relative to the semiconductor processing chamber 1004 such that first ends of the wafer-centering features 1030 protrude out past the first surface 1012 of the showerhead 1008 and towards the pedestal base 1018, e.g., such that the first ends of the wafer-centering features 1030 extend past the second reference plane 1026.

When the second movement mechanism 1038b is actuated into a second position, this may cause the wafer-centering features 1030 to move upward into a second configuration relative to the semiconductor processing chamber 1004 such that the first ends of the wafer-centering features 1030 are above the first surface 1012, or at least at a higher elevation than they were when the second movement mechanism 1038b was in the first position.

When the wafer-centering features 1030 are in the first configuration, the first ends thereof may be located such that one or more radially inward-facing centering surfaces 1032 of the wafer-centering features 1030 are positioned at least partially below the second reference plane 1026 such that when the semiconductor wafer 1002 is caused to move laterally by lateral movement of the pedestal base 1018 due to actuation of the first movement mechanism 1038a during wafer centering operations, the semiconductor wafer 1002 may be caused to come into contact at least one of the one or more radially inward-facing centering surfaces 1032 and be nudged towards the target center point associated with the pedestal base 1018. Such a configuration may also optionally involve moving the pedestal base 1018 along the axis 1028 such that the second reference plane 1026 is at least above the bottommost portion(s) of the one or more radially inward-facing centering surfaces 1032.

In the second configuration shown in FIG. 10b, the wafer-centering features 1030 have been retracted into the pass-through aperatures 1042 of the showerhead 1008 through actuation of the second movement mechanisms 1038b. Such a configuration may reduce anomalies that may develop on the semiconductor wafer due to localized effects of the wafer-centering features 1030 on, for example, a plasma environment developed within the semiconductor processing chamber 1004. Such a configuration may also allow the semiconductor wafer 1002 to be placed onto, or withdrawn from, the pedestal base 1018 during wafer loading/unloading operations, e.g., as discussed earlier.

The semiconductor processing chamber 1004 may also include within it bellows seals 1088a and 1088b. The bellows seals 1088a and 1088b may be configured to provide flexible sealing elements between the pedestal base 1018 and the semiconductor processing chamber 1004 and the support structure that supports the wafer-centering features 1030. The bellows seals 1088a and 1088b may, for example, be metal bellows seals, e.g., made of stainless steel.

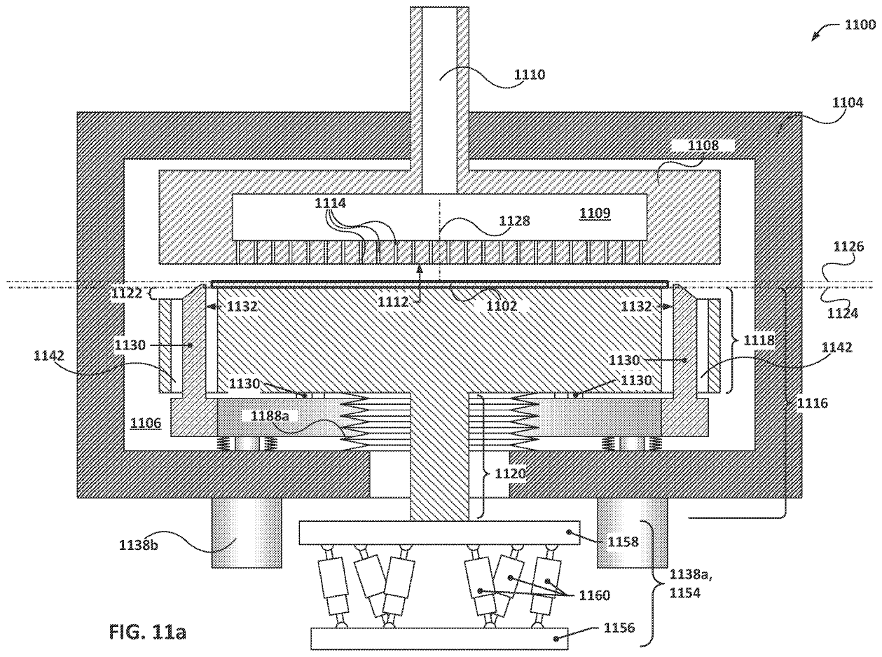

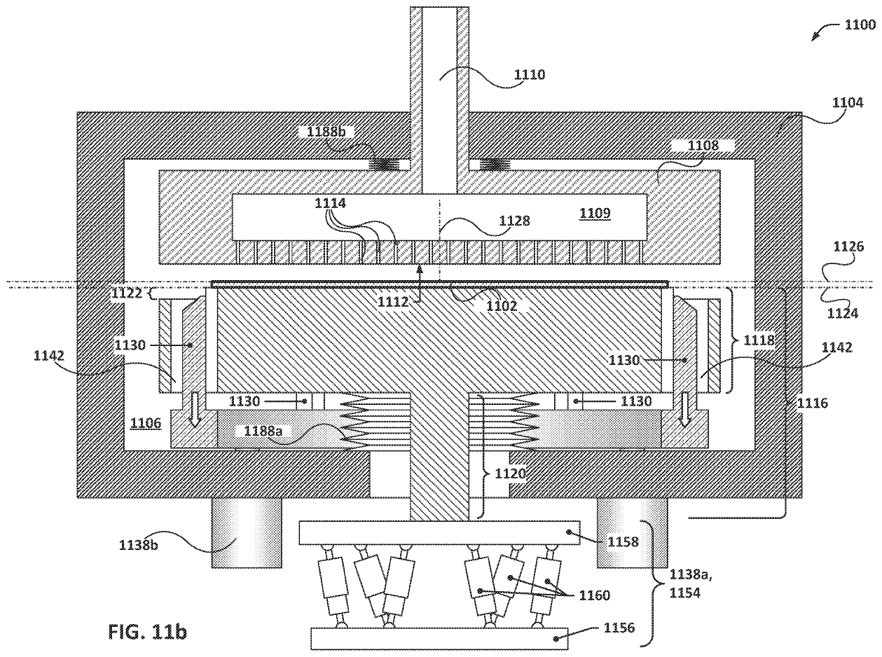

FIGS. 11a and 11b depict an implementation similar that of FIGS. 10a and 10b except that the second movement mechanism 1138b is located on the underside of the semiconductor processing chamber 1104, the support structure supporting the wafer-centering features 1130 is positioned within the interior volume 1106 of the semiconductor processing chamber 1104, and the wafer-centering features 1130 extend upwards through pass-through apertures 1142 in the pedestal base 1118.

As with the example in FIGS. 9a and 9b, the pass-through apertures 1142 may be sized large enough that there is a clearance gap that extends around each wafer-centering feature between the side walls of the pass-through apertures 1142 and the portions of the wafer-centering features 1130 that are located within the pass-through apertures 1142. This clearance gap may be sized such that there is no contact between the wafer-centering features 1130 and the showerhead 1108 when the showerhead 1108 is caused to move along the axis 1128, e.g., through operation of second movement mechanism 1138b. The clearance gap may also be sized to be larger than half the difference between the diameter of the semiconductor wafer 1102 and the reference circle that is defined by the radially inward-facing wafer-centering surfaces 1132 of the wafer-centering features 1130, thereby allowing sufficient clearance between the sidewalls of the pass-through apertures 1142 and the portions of the wafer-centering features 1130 that no contact occurs between the wafer-centering features 1130 and the sidewalls of the pass-through apertures 1142 during lateral movement of the pedestal base 1118 relative to the semiconductor processing chamber 1104 and the wafer-centering features 1130 during wafer-centering operations, e.g., due to lateral movements resulting from actuation of the first movement mechanism 1138a.

The examples discussed herein have, thus far, featured semiconductor processing tools that have each included a plurality of wafer-centering features, e.g., posts, that collectively defined a circular zone or region that acted to “fence” a semiconductor wafer in during lateral movements between the wafer-centering features and the pedestal base. It will be understood, however, that the wafer-centering features discussed herein may take other shapes and forms as well, such as a single circumferential wall that may present an unbroken circular perimeter such that the semiconductor wafer being centered therewith will, if off-center by any amount, come into contact with the circumferential wall at regardless of which in which lateral direction the pedestal base and/or wafer-centering feature is caused to move. The reference circle defined by such a wafer-centering feature is, of course, a circle defined by an interior-facing, axially symmetric surface of such a wafer-centering feature.

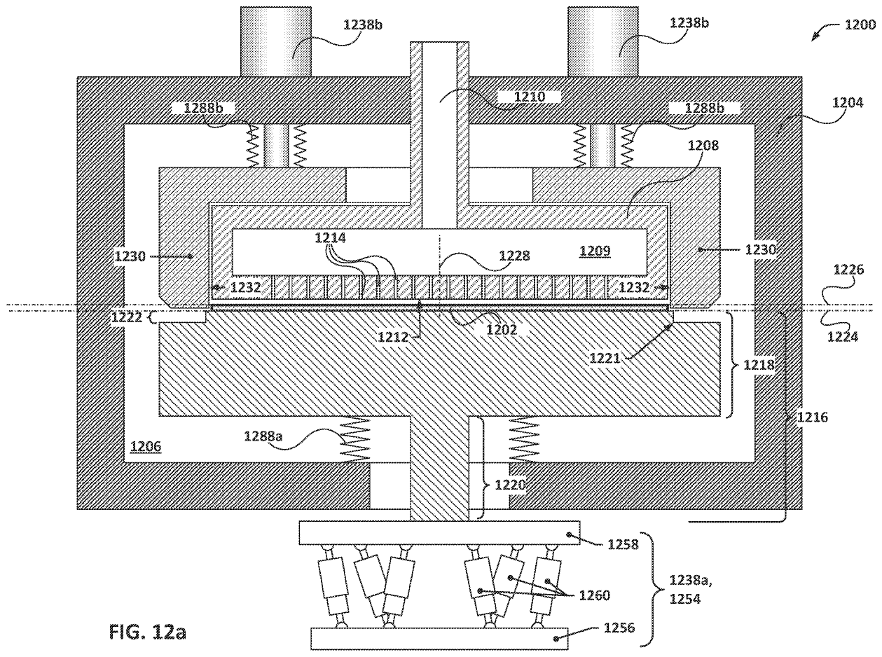

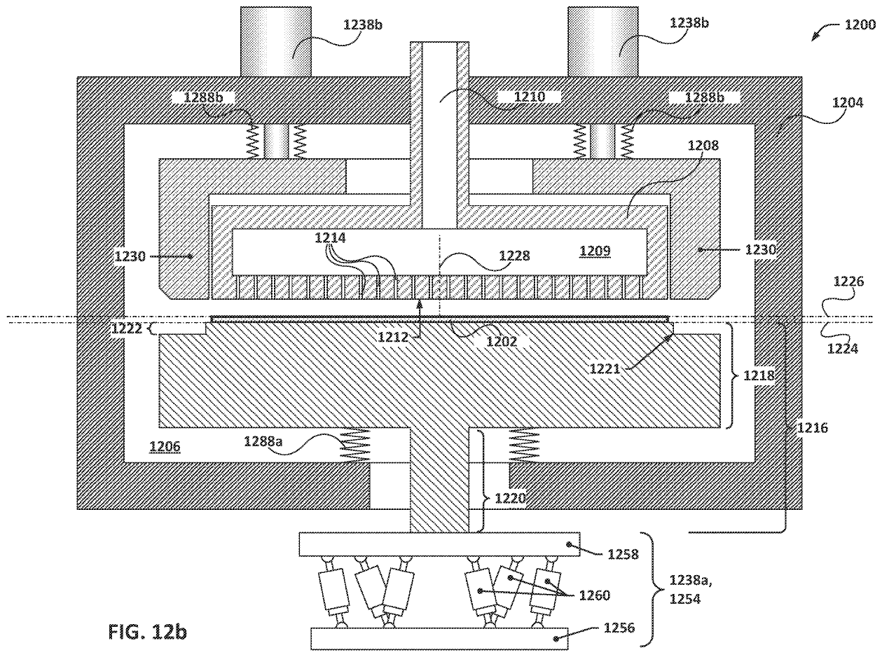

FIGS. 12a and 12b depict such an example semiconductor processing tool. In FIGS. 12a and 12b, the semiconductor processing tool 1200 includes a pedestal 1216 that is supported by a first movement mechanism 1238a within an interior volume of a semiconductor processing chamber 1204. In this example, the one or more wafer-centering features 1230 are provided by an annular collar that includes an annular wall element that encircles the showerhead 1208. The annular wall element is connected with an annular backplate that is, in turn, connected with a second movement mechanism 1238b that is configured to move the annular collar/wafer-centering feature 1230 along the axis 1228 when actuated between a first position, e.g., as shown in FIG. 12a, and a second position, as shown in FIG. 12b. When the one or more second movement mechanisms 1238b are in the first position, the annular wall element of the wafer-centering feature 1230 extends down past the first surface 1212 and past a second reference plane 1226 so that the semiconductor wafer 1202 may come into contact with the annular wall element of the wafer-centering feature 1230 when the semiconductor wafer 1202 is moved laterally relative to the wafer-centering feature, e.g., by the first movement mechanism 1238a.

When the second movement mechanism 1238b is in the second position, the wafer-centering feature 1230 may be lifted upward such that the annular wall element is raised up from the position it was in FIG. 12a, e.g., to a position flush with the underside of the showerhead 1208/first surface 1212. In this configuration, the annular wall element may act as a radial extension of the showerhead 1208, which may help enhance wafer uniformity since any abnormalities that may be associated with the edge of the showerhead 1208 may effectively be moved radially outward to the edge of the annular wall element.

In other implementations, the annular wall element may, similar to the implementation of FIGS. 4a through 4c, be a feature that is fixed with respect to the showerhead 1208. For example, the showerhead 1208 may simply have an inward-facing, axially symmetric surface that extends downward from the first surface 1212. This inward-facing, axially symmetric surface may serve as the radially inward-facing centering surface of a wafer-centering feature.

When the second movement mechanism 1238b is in the first position, lateral movement of the pedestal base 1218 relative to the wafer-centering feature 1230 due to actuation of the first movement mechanism 1238a may cause the semiconductor wafer 1202 to come into contact with the annular wall element that provides the radially inward-facing centering surface 1232 of the wafer-centering feature 1230.

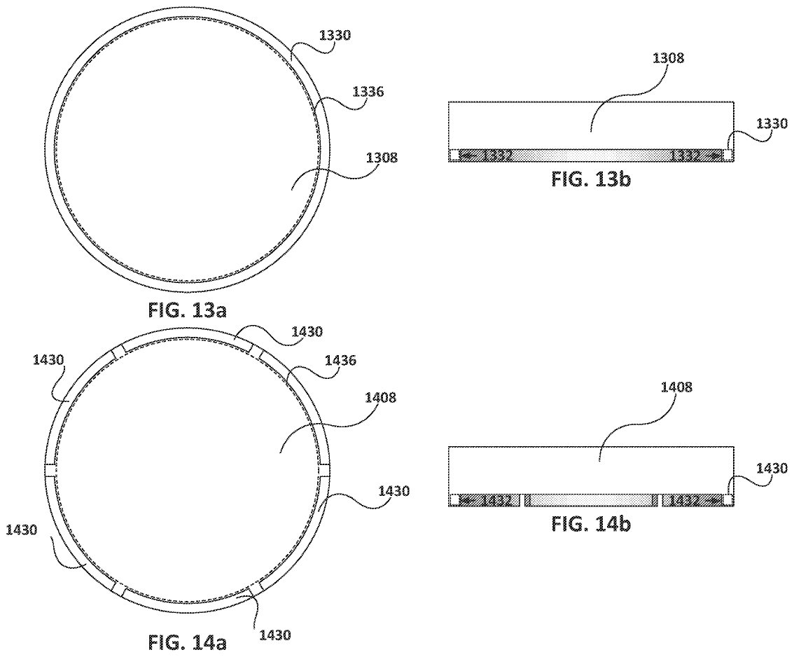

As is likely apparent from the above examples, wafer-centering features that may be used in implementations of the concepts discussed herein may be implemented in a variety of different ways. FIGS. 13a through 16b depict various simplified schematics of three different wafer-centering feature geometries that may be used in some instances. These are but just some examples of potential wafer-centering feature geometries; other geometries that may be used for similar effect are also considered to be within the scope of this disclosure.

FIGS. 13a and 13b depict plan and side cross-section views, respectively, of a showerhead 1308 having a wafer-centering feature 1330 that consists of an axially symmetric wall surface that defines a reference circle 1336 that has a diameter that is larger than a diameter D of the wafer that is to be centered with such a wafer-centering feature 1330.

FIGS. 14a and 14b depict plan and side cross-section views, respectively, of a showerhead 1408 having a plurality of wafer-centering features 1430 that each provide an arcuate radially inward-facing wafer-centering surface. The arcuate radially inward-facing wafer-centering surfaces are arranged so as to be co-radial, e.g., having the same radius and sharing a common center point. As can be seen, the arcuate radially inward-facing wafer-centering surfaces define a reference circle 1436 that has a diameter larger than a diameter D of the wafer that is to be centered with such wafer-centering features 1430. As can be seen, the wafer-centering features 1430 are, in this example, generally arcuate wall segments that are arranged in a circular array and have gaps in between them.

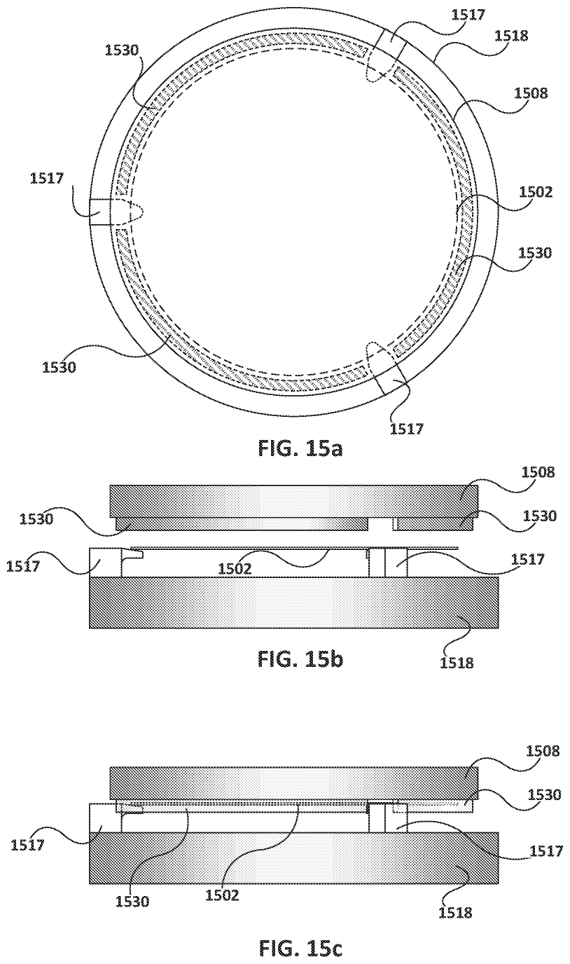

FIGS. 15a through 15c depict top (FIG. 15a) and side views (FIGS. 15b and 15c) of an example showerhead and pedestal base that include wafer-centering functionality similar to that shown in FIGS. 14a and 14b. In FIG. 15a, a top view is shown of a showerhead 1508 that is positioned over a pedestal base 1518. FIG. 15b depicts the showerhead 1508 in an elevated position relative to the pedestal base 1518, e.g., such as may be the case during wafer loading operations. FIG. 15c depicts the showerhead 1508 in a lowered position relative to the pedestal base 1518, e.g., such as may be the case during wafer centering operations. The pedestal base 1518 may have a plurality of spacers 1517—three in this case—extending upward from its top surface. The spacers 1517 may be used to support a semiconductor wafer 1502 above the remainder of the pedestal base 1518 such that the underside of the semiconductor wafer 1502 is, in effect, generally not in contact with any surfaces except small portions of the spacers 1517. As can be seen in FIGS. 15a through 15c, three wafer-centering features 1530 are provided by arcuate walls arranged in a circular array; the arcuate inward-facing surfaces of such arcuate walls may act as radially inward-facing centering surfaces. As can be further seen in FIGS. 15a through 15c, each pair of circumferentially adjacent arcuate walls is separated by a corresponding gap that is sized to be wider than the width of the spacer 1517 at the same radial offset from the center of the pedestal base 1518 as the radial offset of the wafer-centering features 1530 from the center of the showerhead 1508. The gap may be sized such that it is at least as wide as the spacer plus the expected maximum amount of relative displacement between the pedestal base 1518 and the showerhead 1508. When the gap is sized in such a manner, one or both of the pedestal base 1518 and the showerhead 1508 may be moved relative to the other of the pedestal base 1518 and the showerhead 1508 in order to perform wafer-centering operations as discussed earlier herein without the wafer-centering features 1530 colliding with the spacers 1517.

It will be appreciated that the wafer-centering features 1530 in the implementation of FIGS. 15a through 15c may serve a dual purpose—they not only may be used during wafer-centering operations to nudge the wafer on-center, but may also be left in the position shown in FIG. 15c during wafer processing operations, effectively forming a micro-volume that may act to help contain gas flowed into the region above the semiconductor wafer 1502. For example, if the arrangement shown in FIGS. 15a through 15c is used to perform semiconductor processing operations on the top side of the semiconductor wafer 1502, the process gases that may be introduced across the top side of the semiconductor wafer 1502 may be confined to a smaller volume. While such gases may still flow through the circumferential gap between the semiconductor wafer 1502 and the wafer-centering features 1530, as well as through the radial gaps between the spacers 1517 and the wafer-centering features 1530, such gaps may be relatively small and may act as a flow restriction that makes it easier to retain such process gases in the region immediately above the semiconductor wafer 1502 for a longer period of time. In an alternate or additional example, the arrangement of FIGS. 15a through 15c may be used to support backside processing of the semiconductor wafer 1502, e.g., deposition or etch operations performed by flowing process gas towards the underside of the semiconductor wafer 1502. In such implementations, it may be desirable to flow an inert or otherwise non-reactive gas, e.g., nitrogen or argon, across the top of the semiconductor wafer 1502 to shield the top surface of the semiconductor wafer 1502 from potential exposure to process gases that may diffuse into the space above the semiconductor wafer 1502. In such cases, the wafer-centering features 1530 may similarly act as flow restrictions that make it easier to contain the inert or non-reactive gas to the region above the semiconductor wafer 1502. At the same time, such flow restrictions may also hinder the diffusion of the process gas into the space above the semiconductor wafer 1502. Thus, the wafer-centering features 1530 of the implementation of FIGS. 15a through 15c may not only be used for pre-processing wafer-centering operations, but may also serve a functional purpose during wafer processing operations as well.

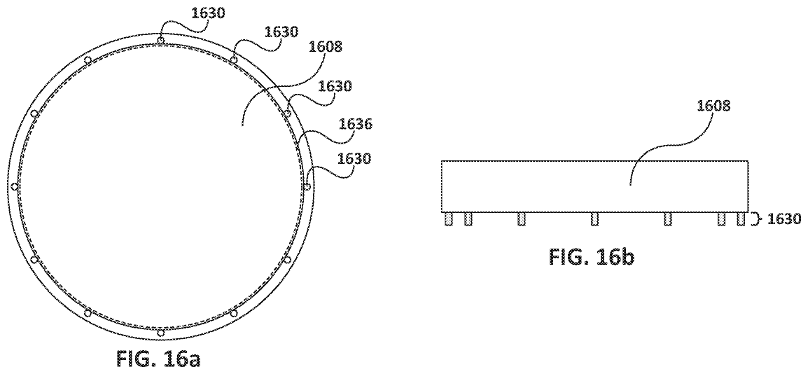

FIGS. 16a and 16b depict plan and side cross-section views, respectively, of a showerhead 1608 having a plurality of wafer-centering features 1630 that are each a cylindrical post that provides an arcuate radially inward-facing wafer-centering surface. The arcuate radially inward-facing wafer-centering surfaces are arranged so as to have center points located outside of a reference circle 1636 that is circumscribed within the circular posts. The reference circle 1636 may have a diameter larger than a diameter D of the wafer that is to be centered with such wafer-centering features 1630.

It will be understood that while the above examples are all provided with respect to wafer-centering features that are part of a showerhead, such geometries may be implemented in any of the examples discussed earlier as well.

The control of semiconductor processing tools as discussed herein, including features relating to wafer centering that are discussed above, as well as potentially other equipment discussed above (such as wafer handling robots, showerheads, etc.) may be facilitated through the use of a controller that may be included as part of a semiconductor processing tool, including, for example, the above-described example semiconductor processing tools and/or chambers. The systems discussed above may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, radio frequency (RF) generator settings, RF matching circuit settings, frequency settings, flow rate settings, fluid delivery settings, positional and operational settings, wafer transfers into and out of a tool or chamber and other transfer tools and/or load locks connected to or interfaced with a specific system. More specifically, such a controller may be configured to control, among other systems, one or more movement mechanisms that may be actuated so as to cause relative movement between a pedestal base and one or more wafer-centering features, as described above. For example, such a controller may be communicatively connected with one or more actuators, motors, or other motion-inducing components of one or more movement mechanisms and may, by causing control signals to be sent thereto, cause such components to perform movements as described above.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. A semiconductor processing tool for processing a semiconductor wafer having a diameter of D and thickness T, the semiconductor processing tool comprising:
a semiconductor processing chamber having a plurality of surfaces defining an interior volume thereof;
a pedestal base configured to support a semiconductor wafer during wafer processing operations, the pedestal base located within the interior volume and including one or more wafer support features that are configured to support the semiconductor wafer when the semiconductor wafer is placed on the pedestal base, wherein the one or more wafer support features define a first reference plane that is coincident with an underside of the semiconductor wafer when the semiconductor wafer is supported by the one or more wafer support features;
a showerhead having a first surface with a plurality of gas distribution ports distributed thereacross, the first surface facing towards, and positioned above, the pedestal base;
one or more wafer-centering features collectively having one or more radially inward-facing wafer-centering surfaces that are positioned radially outward from or circumscribing a reference circle having a diameter of D or greater;
one or more movement mechanisms, the one or more movement mechanisms including at least a first movement mechanism that is configured to move the pedestal base or the one or more wafer-centering features laterally, wherein the first movement mechanism enables the one or more wafer-centering features to adjust a position of the semiconductor wafer relative to the pedestal base while the semiconductor wafer is supported by the pedestal base; and
a controller configured to control at least the first movement mechanism to cause the pedestal base or the one or more wafer-centering features to move relative to the other of the pedestal base or the one or more wafer-centering features.

2. The semiconductor processing tool of claim 1, wherein the one or more wafer-centering features are fixed in space with respect to the showerhead and at least a portion or portions of the one or more radially inward-facing wafer-centering surfaces are located at an elevation lower than the first surface.

3. The semiconductor processing tool of claim 2, wherein the one or more wafer-centering features project downward from the showerhead toward the pedestal base.

4. The semiconductor processing tool of claim 1, wherein the one or more wafer-centering features are fixed in space with respect to the semiconductor processing chamber and extend downward into pass-through apertures in the showerhead.

5. The semiconductor processing tool of claim 4, wherein:
the showerhead and the pedestal base are both configured to be movable along an axis perpendicular to the first reference plane relative to the semiconductor processing chamber,
the showerhead is configured to be movable between a first configuration and a second configuration relative to the semiconductor processing chamber,
first ends of the one or more wafer-centering features extend past the first surface of the showerhead and towards the pedestal base when the showerhead is in the first configuration,
the first ends of the one or more wafer-centering features do not extend past the first surface of the showerhead when the showerhead is in the second configuration,
the pedestal base is configured to be movable between a third configuration and a fourth configuration relative to the semiconductor processing chamber,
the first reference plane is within a distance T of the first ends of the one or more wafer-centering features when the pedestal base is in the third configuration, and
the first reference plane is more than the distance T away from the first ends of the one or more wafer-centering features when the pedestal base is in the fourth configuration.

6. The semiconductor processing tool of claim 1, wherein:
the one or more wafer-centering features extend downward into pass-through apertures in the showerhead,
the semiconductor processing tool further includes one or more actuators configured to be movable between a first position and a second position,
the one or more wafer-centering features are connected, directly or indirectly, with the one or more actuators such that the one or more wafer-centering features move along an axis perpendicular to the first reference plane when the one or more actuators are moved between the first position and the second position,
the one or more wafer-centering features protrude past the first surface of the showerhead when the one or more actuators are in the first position, and
the one or more wafer-centering features are above the first surface of the showerhead when the one or more actuators are in the second position.

7. The semiconductor processing tool of claim 1, wherein the one or more wafer-centering features are fixed in space with respect to the semiconductor processing chamber and extend upward into pass-through apertures in the pedestal base.

8. The semiconductor processing tool of claim 7, wherein:
the first movement mechanism is configured to move the pedestal base both laterally relative to the one or more wafer-centering features and also along an axis perpendicular to the first reference plane,
the first movement mechanism is further configured to move the pedestal base between a first configuration and a second configuration relative to the semiconductor processing chamber,
first ends of the one or more wafer-centering features extend past the first reference plane when the pedestal base is in the first configuration, and
the first ends of the one or more wafer-centering features do not extend past the first reference plane when the pedestal base is in the second configuration.

9. The semiconductor processing tool of claim 1, wherein:
the one or more wafer-centering features extend upward into pass-through apertures in the pedestal base,
the semiconductor processing tool further includes one or more actuators configured to be movable between a first position and a second position,
the one or more wafer-centering features are connected, directly or indirectly, with the one or more actuators such that the one or more wafer-centering features move along an axis perpendicular to the first reference plane and relative to the semiconductor processing chamber when the one or more actuators are moved between the first position and the second position,
the one or more wafer-centering features protrude past the first reference plane when the one or more actuators are in the first position, and
the one or more wafer-centering features are below the first reference plane when the one or more actuators are in the second position.

10. The semiconductor processing tool of claim 1, wherein:
the one or more wafer-centering features include an annular wall element that encircles the showerhead,
the semiconductor processing tool further includes one or more actuators configured to be movable between a first position and a second position,
the annular wall element is connected, directly or indirectly, with the one or more actuators such that the annular wall element moves along an axis perpendicular to the first reference plane when the one or more actuators are moved between the first position and the second position,
the annular wall element protrudes past the first surface when the one or more actuators are in the first position, and
the annular wall element is higher when the one or more actuators are in the second position than when the one or more actuators are in the first position.

11. The semiconductor processing tool of claim 1, wherein the first movement mechanism is configured to move the pedestal base at least laterally relative to the semiconductor processing chamber and the showerhead.

12. The semiconductor processing tool of claim 1, wherein the first movement mechanism is configured to move the showerhead at least laterally relative to the semiconductor processing chamber and the pedestal base.

13. (canceled)

14. (canceled)

15. The semiconductor processing tool of claim 1, wherein:
the one or more radially inward-facing wafer-centering surfaces are a plurality of arcuate surfaces,
each arcuate surface has a radius larger than half of D, and
the arcuate surfaces all have the same radius and share a common center point.

16. The semiconductor processing tool of claim 1, wherein:
the one or more radially inward-facing wafer-centering surfaces are a plurality of radially inward-facing centering surfaces, and
the radially inward-facing centering surfaces circumscribe the reference circle.

17. The semiconductor processing tool of claim 1, wherein the first movement mechanism is a hexapod mechanism including:
a base mount,
a movable mount that supports the one of the pedestal base and the one or more wafer-centering features that the first movement mechanism is configured to move, and
six linear actuators, each linear actuator connected at one end with the base mount and at an opposing end with the movable mount, wherein the hexapod mechanism is configured to cause the movable mount to at least move laterally relative to the base mount, via actuation of the linear actuators, responsive to one or more control signals provided by the controller.

18. The semiconductor processing tool of claim 1, wherein the first movement mechanism includes an XY translation stage having:
a first linear translation mechanism configured to cause the one of the pedestal base and the one or more wafer-centering features that the first movement mechanism is configured to move to translate along a first lateral axis responsive to one or more control signals provided by the controller, and
a second linear translation mechanism configured to cause the one of the pedestal base and the one or more wafer-centering features that the first movement mechanism is configured to move to translate along a second lateral axis responsive to the one or more control signals provided by the controller, wherein the first lateral axis and the second lateral axis are not parallel to one another.

19. (canceled)

20. The semiconductor processing tool of claim 1, wherein the first movement mechanism includes an R-theta mechanism having:
a rotational actuator having a base portion and a rotatable portion,
a linear translation mechanism having a first portion and a second portion, wherein:
the rotational actuator is configured to cause the rotatable portion to rotate about a rotational axis relative to the base portion responsive to one or more control signals provided by the controller,
the linear translation mechanism is configured to cause the second portion to translate along a radial axis relative to the first portion responsive to the one or more control signals provided by the controller,
the second portion of the linear translation mechanism supports the one of the pedestal base and the one or more wafer-centering features that the first movement mechanism is configured to move,
the rotatable portion of the rotational actuator supports the first portion of the linear translation mechanism, and
the radial axis is orthogonal to an axis that is parallel to the rotational axis.

21. The semiconductor processing tool of claim 1, wherein the controller is further configured to control the one or more movement mechanisms to cause the pedestal base and the one or more wafer-centering features to transition between at least a first relative configuration and a second relative configuration, wherein at least a portion of at least one wafer-centering feature of the one or more wafer-centering features is, in the first relative configuration, between the first reference plane and a second reference plane that is parallel to, and positioned a distance T above, the first reference plane and, in the second relative configuration, is not in between the first reference plane and the second reference plane.

22. The semiconductor processing tool of claim 1, wherein the controller is further configured to control the first movement mechanism so as to cause the pedestal base to perform one or more circular orbits having a diameter or diameters less than or equal to the diameter of the reference circle minus D.

23. The semiconductor processing tool of claim 22, wherein the controller is further configured to control the first movement mechanism so as to cause the pedestal base to perform multiple circular orbits having increasingly larger diameters that are each less than or equal to the diameter of the reference circle minus D.

24. (canceled)

25. (canceled)
